(19) United States
(12) Patent Application Publication
(10) Pub. No.: US 2026/0068261 A1
(43) Pub. Date: Mar. 5, 2026

(54) FIELD PLATE INTEGRATION FOR SELF-ALIGNED CONTACT AND METHODS OF MANUFACTURING THE SAME

(71) Applicant: TEXAS INSTRUMENTS INCORPORATED, Dallas, TX (US)

(72) Inventors: Toshiyuki Tamura, Ushiku-Shi (JP); Satoshi Fujita, Aizuwakamatsu-Shi (JP); Tatsuya Kobayashi, Kitakata-Shi (JP); Riku Kobayashi, Keizan (JP); Takayuki Enda, Aizuwakamatsu-Shi (JP); Masahiko Higashi, Aizuwakamatsu-Shi (JP)

(21) Appl. No.: 18/820,877

(22) Filed: Aug. 30, 2024

(51) Int. Cl. H01L 29/40; H01L 29/20; H01L 29/66; H01L 29/778

(52) U.S. Cl. CPC H10D 64/111; H10D 30/015; H10D 30/475; H10D 62/8503; H10D 64/01

(57) ABSTRACT

A device is disclosed herein. The device includes a III-N semiconductor layer disposed over a substrate, a gate structure disposed over the III-N semiconductor layer, and a field plate disposed over the gate structure. The field plate includes a first conductive layer disposed over the gate structure, a second conductive layer disposed over the first conductive layer, the second conductive layer having a different material composition than the first conductive layer, and a third conductive layer disposed over the second conductive layer, the third conductive layer having a different material composition than the first and second conductive layers. The device further includes a contact coupled to the field plate and the III-N semiconductor layer.

### FIELD

The present disclosure generally relates to semiconductor devices, and more particularly, to semiconductor devices including a field plate.

### BACKGROUND

A type of semiconductor device is a high electron mobility transistor (HEMT). A HEMT typically employs different semiconductor materials to form a heterojunction, where a channel may be formed near the heterojunction and between a source and a drain. A HEMT may support a high-speed operation, which makes HEMTs attractive for high frequency applications, among others.

### SUMMARY

A semiconductor device is disclosed herein. The device includes a III-N semiconductor layer disposed over a substrate, a gate structure disposed over the III-N semiconductor layer, and a field plate disposed over the gate structure. The field plate includes a first conductive layer disposed over the gate structure, a second conductive layer disposed over the first conductive layer, the second conductive layer having a different material composition than the first conductive layer, and a third conductive layer disposed over the second conductive layer, the third conductive layer having a different material composition than the first and second conductive layers. The device further includes a contact coupled to the field plate and the III-N semiconductor layer.

Also disclosed herein is a method. The method includes forming a III-N semiconductor layer over a substrate, forming a gate structure over the III-N semiconductor layer, forming a first conductive layer over the gate structure, forming a second conductive layer over the first metal layer, the second conductive layer having a different material composition than the first conductive layer, patterning the second conductive layer, wherein the patterning of the second conductive layer forms a protective layer on a sidewall of the patterned second conductive layer, patterning the first conductive layer while using the protective layer and the patterned second layer as a mask, forming a first dielectric layer over the patterned first and second conductive layers, forming a contact opening through the first dielectric layer to at least the III-N semiconductor layer, wherein the patterned first and second conductive layers are exposed in the contact opening, and forming a contact in the contact opening.

Also disclosed herein is a method including forming a III-N semiconductor layer over a substrate, forming a gate structure over the III-N semiconductor layer, forming a field plate over the gate structure, forming a first dielectric layer over the field plate such that the first dielectric layer covers the field plate, performing a first etching process using a first etchant to remove a first portion of the first dielectric layer, wherein a second portion of the first dielectric layer still covers the field plate after the performing of the first etching process, performing a second etching process using a second etchant to remove the second portion of the first dielectric layer and at least a portion of the III-N semiconductor layer to form a contact opening, the second etchant being different than the first etchant, and forming a contact in the contact opening.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flowchart for a method of forming a semiconductor device, in accordance with various examples.

FIGS. 2A, 2B, 2C, 2D, 2E, 2F, 2G, 2H, and 2I illustrate cross-section views of a semiconductor device, in accordance with the process of FIG. 1 and the various examples associated therewith.

FIG. 3 illustrates a flowchart for a method of forming a semiconductor device, in accordance with various examples.

FIGS. 4A, 4B, 4C-1, 4C-2, 4D-1, 4D-2, 4E-1, 4E-2, 4F, 4G-1, 4G-2, 4H, 4I, 4J, 4K, and 4L illustrate cross-section views of a semiconductor device, in accordance with the process of FIG. 3 and the various examples associated therewith.

FIG. 5 illustrates a flowchart for a method of forming a semiconductor device, in accordance with various examples.

FIGS. 6A, 6B, 6C, 6D, 6E, and 6F illustrate cross-section views of a semiconductor device, in accordance with the process of FIG. 5 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

The present disclosure relates generally, but not exclusively, to semiconductor processing for self-aligned contact structures and corresponding semiconductor devices, such as high electron mobility transistors (HEMTs). Generally, a semiconductor device, such as a HEMT, may include a channel layer, a barrier layer, a gate stack, and a field plate. The barrier layer is disposed over the channel layer. The gate stack is disposed over the barrier layer. The field plate is disposed over the gate stack and may extend laterally away from the gate stack toward and over a source region of the HEMT, which is at least partially defined in the channel layer. As such, the field plate, in some examples, may function as a contact etch stop layer during the source contact trench formation which subsequently facilitates forming a self-aligned contact structure.

Disclosed herein are methods of forming HEMTs having self-aligned contact structures, including using field plates to facilitate the forming of self-aligned contact structures. During the formation of self-aligned contact structures, over etching of a field plate may occur which may cause electrical and/or structural issues with the semiconductor device, such as a HEMT. In various examples, the electrical and/or structural issues may include shorting effects and capacitance issues caused by exposing a portion of a gate electrode and/or the field plate being thinned too much during contact formation such that the field plate no longer provides adequate buffer (e.g. thickness) between a contact and a gate electrode of the transistor. The examples described herein avoid such electrical and/or structural issues that may occur during semiconductor processes for forming self-aligned contact structures in transistors, including HEMTs, having field plates.

Using the methods disclosed herein, the over etching damage to different layers of the HEMT (e.g., the field plate, the barrier layer, the channel layer, etc.) that occurs during the formation of the contact structure may be obviated. In various examples disclosed herein, the composition of the field plate may be altered such that the etch rate of the field plate is greatly reduced, which in turn may prevent over etching of the field plate during the formation of self-aligned contact structures. The methods disclosed herein also improve on semiconductor processes using the combination of unique field plate structures and methods of etching that reduce and/or prevent over etching of the field plate structures during the formation of self-aligned contact structures.

Disclosed herein, in various examples, is a HEMT including a field plate formed of a material with a reduced etch rate relative to the surrounding layers such that over etching of the field plate is reduced and/or prevented during the formation of self-aligned contact structures. In various examples, the field plate may be a single material layer or may include multiple layers of a same material composition. In various examples, the field plate formed of a single layer or multiple layers of a same material composition may include aluminum (Al), cobalt (Co), silicon chromium (SiCr), and/or silicon carbide chromium (SiCCr).

In other various examples, a multilayered field plate is provided which includes multiple layers where each layer may have the same or different material composition than other layers of the field plate. In various examples, a multilayered field plate may include a titanium-containing layer and an aluminum-containing layer. In various examples, a multilayered field plate may include a first titanium-containing layer, an aluminum-containing layer, and a second titanium-containing layer. In some examples, the first titanium-containing layer has a different material composition than the second titanium-containing layer. In various examples, one or more layers of the multilayered field plate are formed of a material having a reduced etch rate relative to the surrounding layers such that over etching of the field plate is reduced and/or prevented during the formation of self-aligned contact structures.

Also disclosed herein are methods for forming the field plates described above. In various examples, the formation of the field plate may occur by one or more etching processes that may include one or more etchants that prevent damage from occurring during the formation of the field plate. For example, boron trichloride (BCl₃) and/or chlorine (Cl₂) may be used to limit and/or prevent damage from occurring during the formation of the field plate.

Additionally, disclosed herein are methods for forming self-aligned contact structures utilizing one or more etching processes that limit and/or avoid damage to the field plate during the self-aligned contact formation process. In various examples, one or more etching processes may include one or more etchants that have a high selectivity to the one or more dielectric layers surrounding the field plate. As a result, in some examples, such etch selectivity of the dielectric material in the one or more surrounding dielectric layers over the one or more of the material layers of the field plate mitigates and/or prevents over etching of the field plate from occurring during the formation of the self-aligned contact structure. Additional benefits and examples will become apparent in the description below.

Various examples are described subsequently. Although the specific examples may illustrate various aspects of the above generally described features, examples may incorporate any combination of the above generally described features (which are described in more detail in examples below).

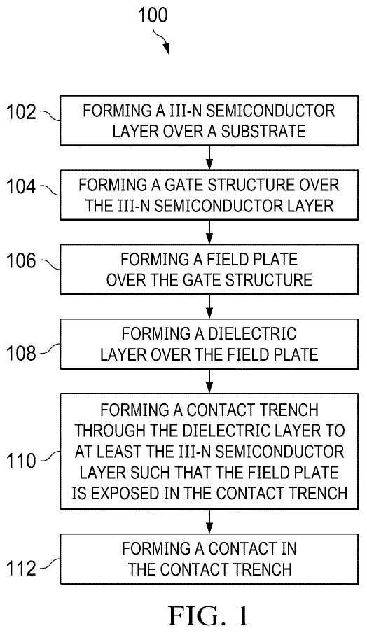

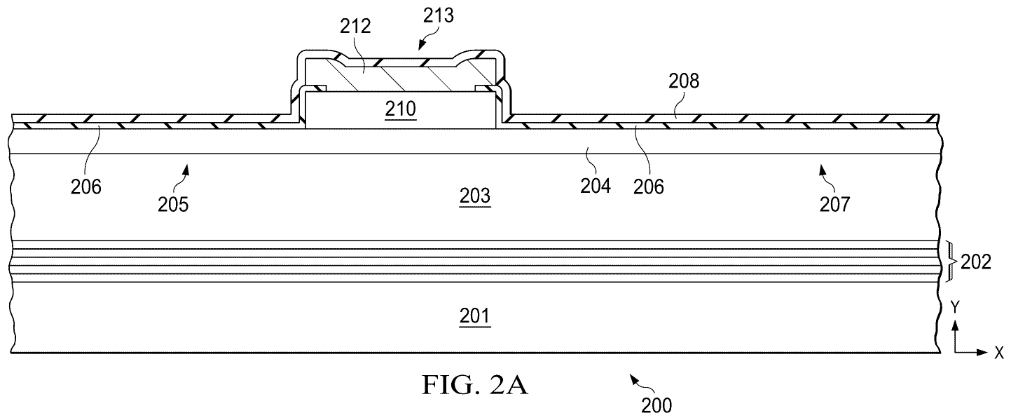

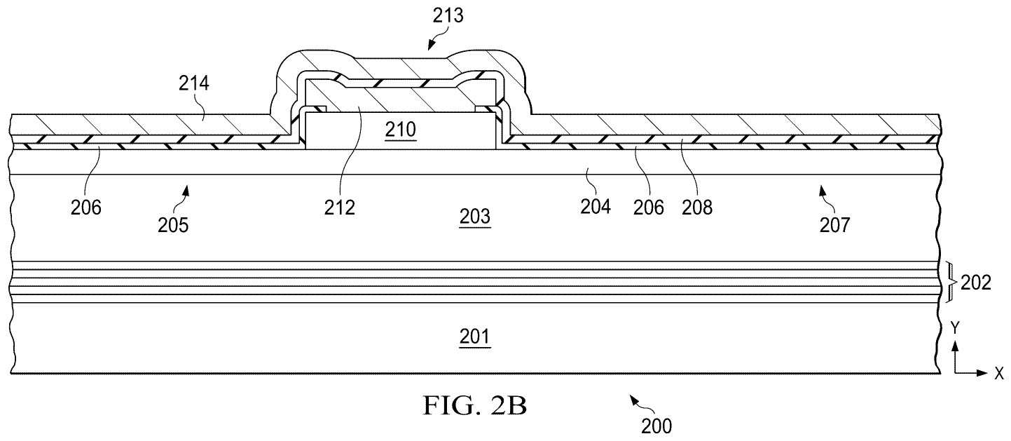

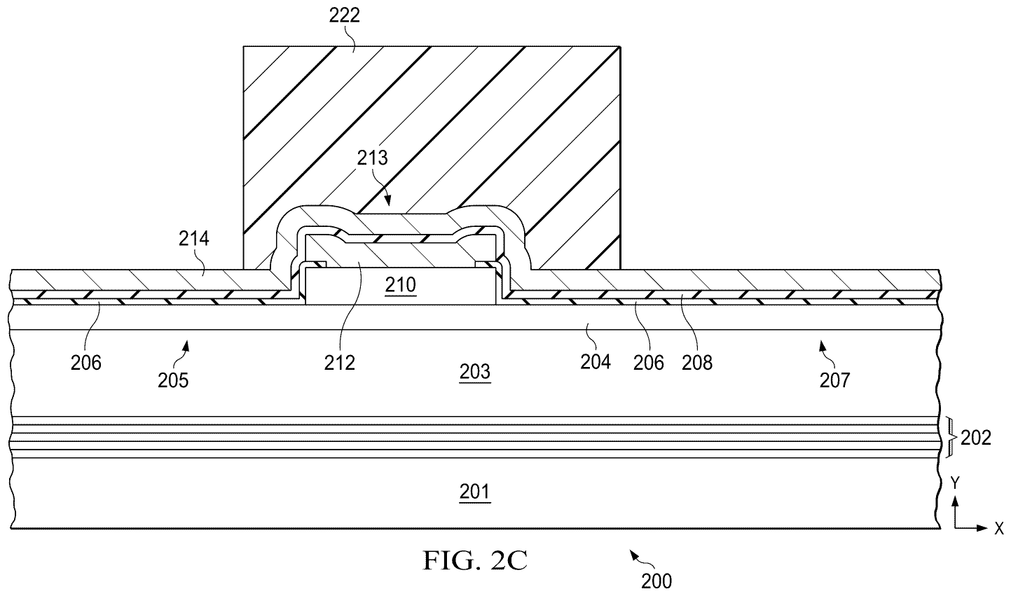

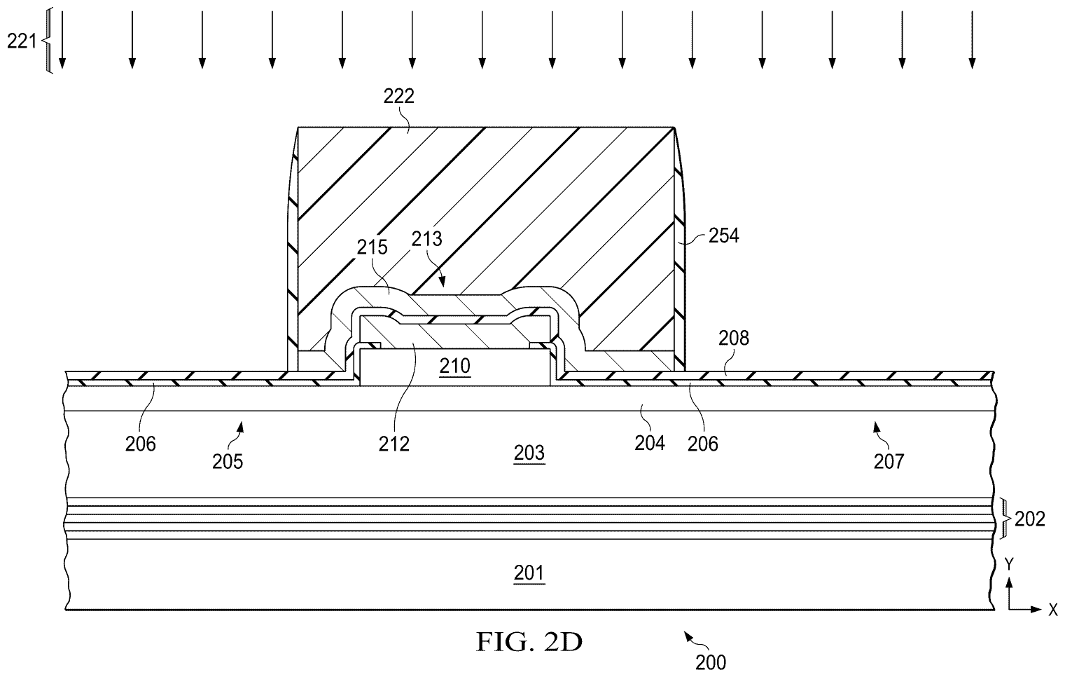

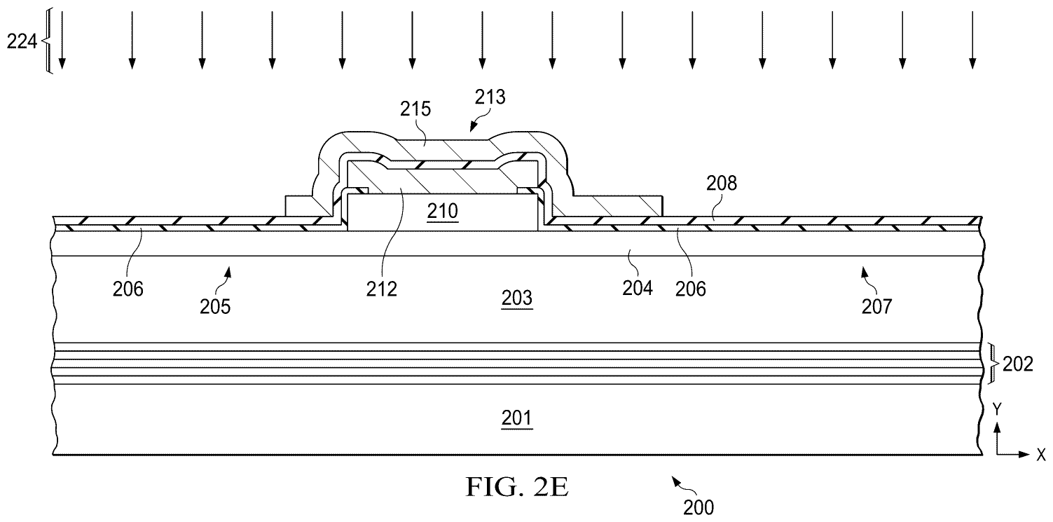

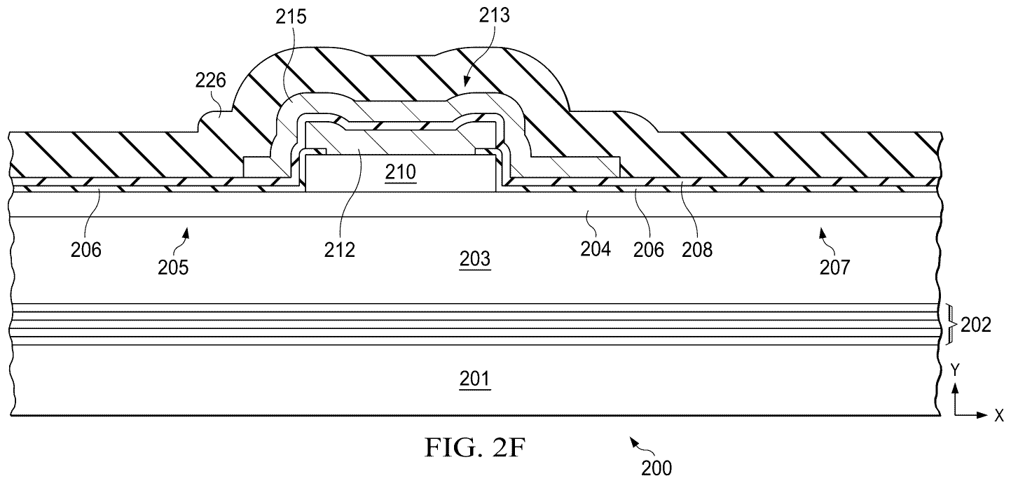

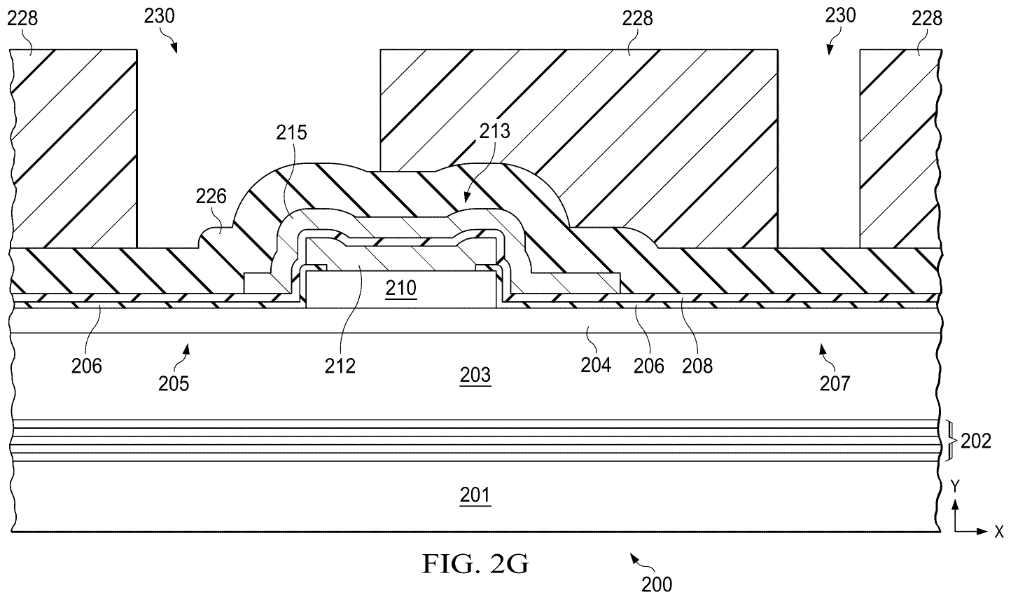

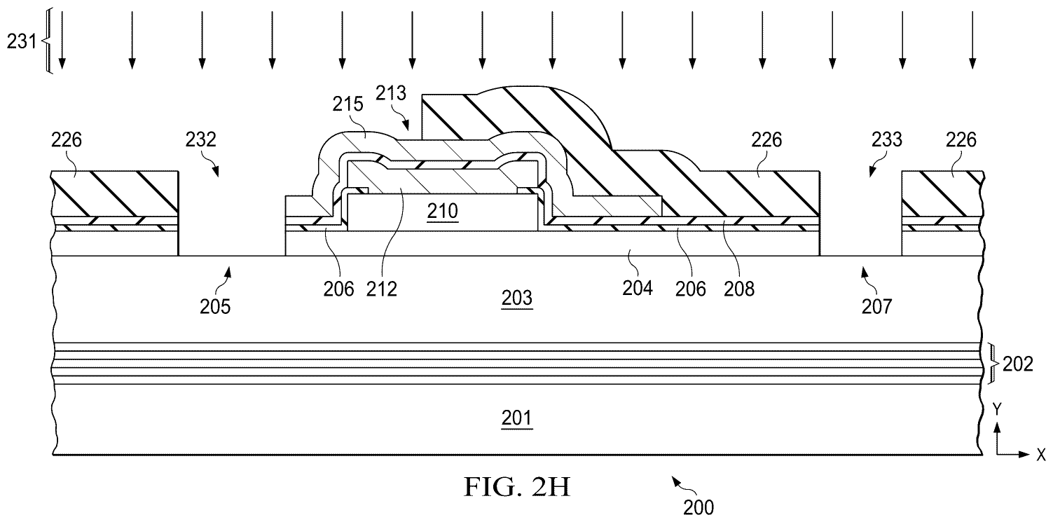

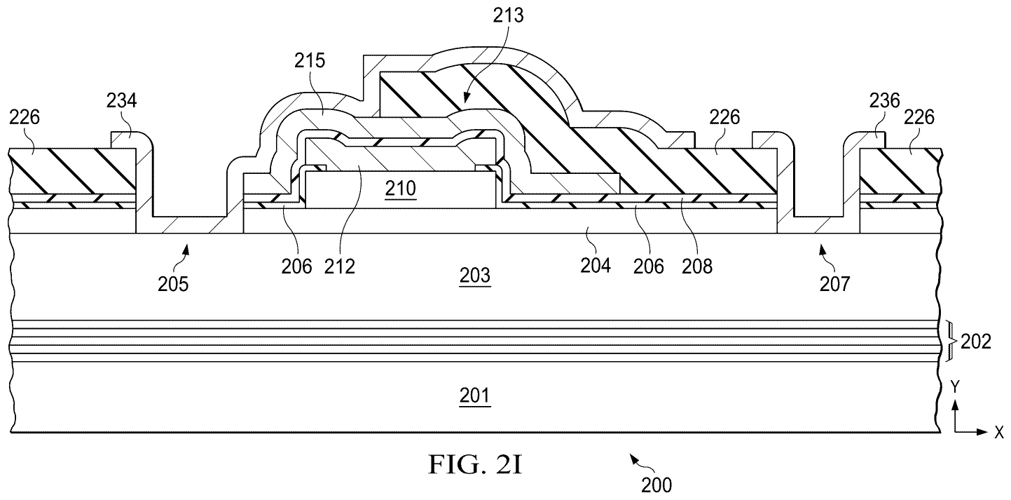

Referring now to FIG. 1, a flow diagram of a method 100 of forming a self-aligned contact using a field plate of a field effect transistor (FET) is illustrated, in accordance with various examples of the present disclosure. In various examples, method 100 may be used to form a field plate allowing for self-aligned contact openings in semiconductor devices, such as high electron mobility transistors (HEMTs). Additional processes can be provided before, during, and after method 100. As described below, method 100 is described with reference to FIGS. 2A-2I.

In that regard, FIGS. 2A-2I are diagrammatic cross-sectional views of a device 200 at various stages of fabrication (such as those associated with method 100 of FIG. 1) according to various aspects of the present disclosure. In various examples, device 200 is or includes an enhancement mode (E-mode) HEMT. Device 200 may be rated for a low voltage (LV) application (e.g., equal to or less than about 100 V), a medium voltage (MV) application (e.g., about 100 V to about 300 V), or a high voltage (HV) application (e.g., equal to or greater than about 400 V). Note that a semiconductor device that is rated for a LV, MV, or HV application does not indicate a particular threshold voltage for that semiconductor device. Instead, the voltage rating of the semiconductor device may be based, at least in part, on a lateral distance between a drain region and a source region of the semiconductor device. For example, a semiconductor device rated for a HV application may have a magnitude of the threshold voltage that is low. Conversely, a semiconductor device rated for a LV application may have a magnitude of a threshold voltage that is high. Additional features can be added to device 200, and some features described below can be replaced, modified, or eliminated in other examples of device 200.

At step 102 and 104 of FIG. 1, a III-N semiconductor layer is formed over a substrate and a gate structure is formed over the III-N semiconductor layer. As shown in FIG. 2A, device 200 includes a semiconductor substrate 201, one or more transition layers 202, a channel layer 203, a barrier layer 204, a source region 205, a drain region 207, a first dielectric layer 206, a second dielectric layer 208, a gate layer 210, and a gate electrode 212. Barrier layer 204 is formed over semiconductor substrate 201, including over transition layers 202 and channel layer 203. More specifically, transition layers 202 are formed over semiconductor substrate 201, channel layer 203 is formed over transition layers 202, and barrier layer 204 is formed over channel layer 203. Gate layer 210 is formed over barrier layer 204 and first dielectric layer 206 is formed over barrier layer 204 and gate layer 210. Gate electrode 212 is formed over gate layer 210 and first dielectric layer 206. Second dielectric layer 208 is formed over first dielectric layer 206 and gate electrode 212.

Semiconductor substrate 201 may be a bulk semiconductor substrate, a semiconductor-on-insulator (SOI) substrate, or any other appropriate substrate. For example, the semiconductor substrate 201 may be or include a bulk silicon wafer. Transition layers 202 may include any number of layers of any materials that are configured to accommodate lattice mismatch between semiconductor substrate 201 and channel layer 203 (e.g., to reduce or minimize lattice defect generation and/or propagation in the channel layer 203). For example, transition layers 202 may have a gradient concentration of one or more elements in a direction normal to the upper surface of semiconductor substrate 201. Further, one or more layers of transition layers 202 may be a doped buffer layer.

Channel layer 203, in some examples, may be a portion of a semiconductor substrate (e.g., without transition layers 202), and/or semiconductor substrate 201 with transition layers 202 and channel layer 203 may be considered a semiconductor substrate. In some examples, channel layer 203 includes a gallium nitride (GaN) layer and, in such examples, may be referred to as a GaN channel layer. In some examples, the material of channel layer 203 is or includes an unintentionally doped material, such as a material doped by diffusion of dopants from another layer. Accordingly, in various examples, channel layer 203 may be referred to as an unintentionally doped (UID) layer.

Barrier layer 204, in some examples, may be or may include an aluminum gallium nitride (AlGaN) layer and, in such examples, may be referred to as an AlGaN barrier layer (or III-N semiconductor layer). In some examples, channel layer 203 may be or may include indium aluminum gallium nitride (InᵢAlⱼGa₁₋ᵢ₋ⱼN) (where 0≤i≤1, 0≤j≤1, and 0≤i+j≤1), and barrier layer 204 may be or may include indium aluminum gallium nitride (InₖAlₗGa₁₋ₖ₋ₗN) (where 0≤k≤1, 0≤l≤1, and 0≤k+l≤1). Other materials may be implemented for the channel layer 203 and/or the barrier layer 204.

For the purposes of this description, the term “III-N” is understood to refer to semiconductor materials in which group III elements, such as aluminum, gallium, and indium, and possibly boron, provide a portion of the atoms in the semiconductor material and nitrogen atoms provide another portion of the atoms in the semiconductor material. Examples of III-N semiconductor materials include gallium nitride, boron gallium nitride, aluminum gallium nitride, indium nitride, and indium aluminum gallium nitride. Additionally, terms describing elemental formulas of materials do not imply a particular stoichiometry of the elements. For example, aluminum gallium nitride may be written as AlGaN, which covers a range of relative proportions of aluminum and gallium.

Channel layer 203 is configured, in conjunction with barrier layer 204, to conduct and confine charge carriers (such as electrons) within two dimensions. That is, charge carriers can be formed at an interface of such a heterojunction structure having two dissimilar semiconductor materials in contact with each other (e.g., the channel layer 203 and the barrier layer 204). In some examples, channel layer 203 and barrier layer 204 may collectively be referred to as a GaN heterojunction structure. In various examples, the charge carriers are induced at or near the surface of channel layer 203, which is in contact with barrier layer 204, at least partially due to conduction-band offset between the two semiconductor materials (e.g., GaN and AlGaN). Moreover, the charge carriers may be induced by polarization discontinuity present in the GaN heterojunction structure. Such a layer of highly mobile electrons may be referred to as a 2-dimensional electron gas (2DEG), a 2DEG layer, or charge carriers.

Gate layer 210 may then be formed over barrier layer 204. In some examples, gate layer 210 is or includes a semiconductor layer of a semiconductor material. Further, in some examples, gate layer 210 is doped with a dopant. In some examples, gate layer 210 is doped with a p-type dopant. Accordingly, gate layer 210 may also be referred to as a p-type III-N semiconductor material. In some examples, gate layer 210 may be or include a gallium nitride (GaN) layer, such as indium aluminum gallium nitride (InₘAlₙGa₁₋ₘ₋ₙN) (where 0≤m<1, 0≤n<1, and 0≤m+n≤1), and the dopant with which gate layer 210 is doped is a p-type dopant, which may be or include magnesium (Mg), carbon (C), zinc (Zn), the like, or a combination thereof. In examples in which gate layer 210 is gallium nitride (GaN) doped with a p-type dopant, gate layer 210 may be referred to as a p-doped GaN (pGaN) layer. Further, in examples in which gate layer 210 is gallium nitride (GaN) doped with a magnesium, gate layer 210 may be referred to as a magnesium doped gallium nitride (GaN:Mg) layer. In some examples, a concentration of the dopant in gate layer 210, which is electrically activated, is equal to or greater than 1×10¹⁷ cm⁻³. In some examples, the concentration is equal to or greater than 1×10¹⁸ cm⁻³. In some examples, the dopant in gate layer 210 may have a uniform concentration. In some examples, the dopant in gate layer 210 may have a gradient concentration. Other materials, dopants, and/or concentrations may be implemented in other examples.

In some examples, transition layers 202, channel layer 203, barrier layer 204, and gate layer 210 may be formed by using any appropriate deposition process. In various examples, the deposition process may include an epitaxial growth process. For example, transition layers 202, channel layer 203, barrier layer 204, and gate layer 210 may each be epitaxially grown using metal-organic chemical vapor deposition (MOCVD), molecular beam epitaxy (MBE), low pressure chemical vapor deposition (LPCVD), and/or another epitaxy process. In some examples, gate layer 210 may be doped in situ during deposition (e.g., epitaxial growth) or by implantation (e.g., ion implantation) subsequent to deposition.

First dielectric layer 206 (e.g., a first passivation layer) is formed over barrier layer 204 and gate layer 210. In various examples, first dielectric layer 206 may include one or more layers of silicon oxide, silicon nitride, silicon oxynitride, aluminum oxide (Al₂O₃), aluminum nitride (AlN), aluminum oxynitride (AlON), hafnium oxide (HfO₂), any other dielectric material, or any combination thereof. First dielectric layer 206 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example. An opening may be formed through first dielectric layer 206 to expose an upper portion of gate layer 210. The opening may be formed using a patterning and etching process to remove the portions of first dielectric layer 206 over gate layer 210 to expose gate layer 210.

Gate electrode 212 is formed over first dielectric layer 206 and over the exposed portions of gate layer 210. In various examples, gate electrode 212 may be formed using one or more deposition processes, such as sputtering, physical vapor deposition (PVD), chemical vapor deposition (CVD), or the like, or any combination thereof. In various examples, gate electrode 212 may include titanium, nickel, titanium nitride, titanium tungsten, tungsten, or a combination thereof. Other metals for gate electrode 212 are within the scope of this disclosure such that gate electrode 212 may include or be any appropriate metal and/or metal alloy. In some examples, gate electrode 212 may form a Schottky junction with gate layer 210. As examples, when the gate layer 210 is magnesium doped gallium nitride (GaN:Mg), metal that may form a Schottky junction with gate layer 210 may be or include titanium (Ti), titanium tungsten (TiW), titanium nitride (TiN), nickel (Ni), platinum (Pt), tantalum nitride (TaN), copper (Cu), tungsten (W), or alloys thereof. In some examples, gate electrode 212 may form an ohmic junction with gate layer 210. As examples, when gate layer 210 is magnesium doped gallium nitride (GaN:Mg), metal that may form an ohmic junction with gate layer 210 may be or include gold (Au), nickel (Ni), aluminum (Al), or alloys thereof, which alloys may include titanium tungsten aluminum (TiWAl) and titanium aluminum nitride (TiAlN). In some examples, gate electrode 212 includes a first portion including a metal that forms a Schottky junction with gate layer 210 and a second portion including a metal that forms an ohmic junction with gate layer 210, such as described in U.S. patent application Ser. No. 18/361,997, filed Jul. 31, 2023, which is incorporated by reference herein in its entirety.

As shown, gate layer 210 and gate electrode 212 form a gate stack 213 (e.g., gate structure). The method may include a photolithographic pattern and etch process to define and etch gate electrode 212 as part of forming gate stack 213. During the formation of gate stack 213, a gate mask (not shown) is formed over gate electrode 212, the gate mask covering an area of gate electrode 212 and the underlying gate layer 210. In various examples, the gate mask may include photoresist, formed by a photolithographic process. The formation process of gate stack 213 may then continue with a gate etch process which removes portions of gate electrode 212 where exposed by the gate mask, leaving gate electrode 212 and gate layer 210 under the gate mask to form gate stack 213.

Second dielectric layer 208 (e.g., a second passivation layer) is then formed over first dielectric layer 206 and gate electrode 212. As shown, second dielectric layer 208 may be conformally formed over and on the upper surface of first dielectric layer 206 and on and along the sidewalls and an upper surface of gate electrode 212. In some examples, second dielectric layer 208 may be or include silicon nitride, silicon oxide, silicon oxynitride, aluminum oxide (Al₂O₃), aluminum nitride (AlN), aluminum oxynitride (AlON), hafnium oxide (HfO₂), any other dielectric material, or a combination thereof. In some examples, second dielectric layer 208 may include the same material(s) as first dielectric layer 206 such that the two dielectric layers have substantially the same material composition. In other examples, second dielectric layer 208 may include different material(s) than first dielectric layer 206 such that the two dielectric layers have substantially different material compositions. Second dielectric layer 208 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example. In various examples, second dielectric layer 208 may be formed by the same process as first dielectric layer 206. In various other examples, second dielectric layer 208 may be formed by a different process than first dielectric layer 206. For example, first dielectric layer 206 may be formed using one or more LPCVD processes and second dielectric layer 208 may be formed using one or more PECVD processes.

Additionally, as shown, device 200 further includes source region 205 and drain region 207. A channel region extends laterally between source region 205 and drain region 207 and within channel layer 203. More specifically, the channel region underlies gate stack 213 (e.g., a gate terminal). Within HEMTs, such as device 200, charge carriers (e.g., two-dimensional electron gas (2DEG)) are formed in channel layer 203, including in the channel region, source region 205, and drain region 207. For example, the charge carriers are formed at the surface of channel layer 203 that is in contact with barrier layer 204. This provides a channel for current conduction (e.g., channel layer 203) between source region 205 and drain region 207. As such, the channel region between source region 205 and drain region 207 may be referred to as a surface channel or a device channel. Moreover, gate electrode 212 is positioned between source region 205 and drain region 207 to control the current conduction through channel layer 203. HEMTs can be configured as enhancement-mode (E-mode HEMT) devices, like device 200 for example, or depletion-mode HEMT (D-mode HEMT). The E-mode HEMTs are configured to have electrons of the charge carriers (e.g., two-dimensional electron gas) depleted (e.g., absent) under gate electrode 212 resulting in normally OFF devices. The E-mode HEMTs can be turned ON by applying a positive voltage to gate electrode 212. On the other hand, the D-mode HEMTs are configured to have the charge carriers (e.g., two-dimensional electron gas) present under a gate electrode resulting in normally ON devices. The D-mode HEMTs devices can be turned OFF by applying a negative voltage to the gate electrode. It is understood that the methods and structures disclosed herein are applicable to both E-mode HEMTs and D-mode HEMTs.

At step 106 of FIG. 1, a field plate is formed over the gate structure. As shown in FIGS. 2B-2E, field plate 215 is formed over second dielectric layer 208. With respect to FIG. 2B, a conductive layer 214 (e.g. metal layer) is formed over second dielectric layer 208. In various examples, conductive layer 214 may be a metal or metal alloy among other conductive materials. In various examples, the metal and/or metal alloy may include aluminum (Al), cobalt (Co), silicon chromium (SiCr), and/or silicon carbide chromium (SiCCr). Conductive layer 214 may be deposited using a physical vapor deposition (PVD) deposition method or other suitable process techniques. Conductive layer 214 may be a single material layer or may include multiple layers of a same material composition. As described in further detail below, the composition of conductive layer 214 is selected based on its etch rate relative to surrounding material layers. That is, the material composition of conductive layer 214 has a low etch rate relative to other material layers surrounding the later formed field plate. As such, over etching of the field plate is mitigated and/or prevented during the formation of the self-aligned contact structure.

Referring now to FIG. 2C, a patterned first photoresist layer 222 is formed over conductive layer 214. First photoresist layer 222 may be formed, in various examples, by a photolithographic process. In various examples, first photoresist layer 222 may include a negative photoresist material or a positive photoresist material. First photoresist layer 222 may be patterned using one or more exposure and develop processes. As described below, patterned first photoresist layer 222 defines the area of field plate 215 formed from patterning conductive layer 214.

Referring now to FIG. 2D, a first etching process is performed to form field plate 215. First etching process 221 removes portions of conductive layer 214 that are not covered by first photoresist layer 222 to form field plate 215. The first etching process 221 exposes a portion of second dielectric layer 208. Also, the first etch process causes a protective layer 254 to form on sidewalls of first photoresist layer 222 and on sidewalls of field plate 215. In various examples, protective layer 254 may be a polymer by-product of the first etching process 221. In various examples, protective layer 254 may be a metal or metal alloy-containing polymer such as an aluminum-containing polymer. The formation of protective layer 254 on sidewalls of first photoresist layer 222 and on sidewalls of field plate 215 protects these layers from being over etched and/or damaged during first etching process 221.

In various examples, the first etching process 221 may include one or more etching processes. In various examples, the one or more etching processes may be a wet etch process, a dry etch process, or combinations thereof. The one or more etching processes may be tuned to remove exposed portions of conductive layer 214 with little to no etching of second dielectric layer 208. Different parameters of the first etching process 221 may be tuned for the desired application, including an etchant type, an etchant flow rate, a chamber pressure, an RF power, a bias RF power, and a process time. In various examples, the etchant may be boron trichloride (BCl₃) and/or chlorine (Cl₂). In various examples, the flow rate of the BCl₃ etchant may be about 30 sccm to about 70 sccm, and more specifically, about 45 sccm to about 55 sccm. In various examples, the flow rate of the Cl₂ etchant may be about 5 sccm to about 35 sccm, and more specifically, about 15 sccm to about 25 sccm. In various examples, the chamber pressure may be about 5 mTorr to about 25 mTorr, and more specifically, about 10 mTorr to about 20 mTorr. In various examples, the RF power may be about 350 W to about 550 W, and more specifically, about 425 W to about 475 W. In various examples, the bias RF power may be about 350 W to about 550 W, and more specifically, about 420 W to about 470 W. In various examples, the process time may be about 15 seconds to about 45 seconds, and more specifically, about 24 seconds to about 32 seconds.

Referring now to FIG. 2E, a removal process 224 may be performed to remove protective layer 254 and first photoresist layer 222 from over semiconductor substrate 201. In various examples, removal process 224 may include one or more etching processes. In various examples, the one or more etching processes may include a wet etch process, a dry etch process, or a combination thereof. In some examples, removal process 224 may include a plasma ashing process. FIG. 2E illustrates device 200 in which field plate 215 is for a source side field plate. It is understood that similar processes may be performed to form a drain side field plate. The portion of conductive layer 214 that remains after removal process 224 functions as field plate 215, and in various examples, a contact etch stop layer during formation of a self-aligned contact structure.

Field plate 215 functions as a field plate (e.g., reducing the maximum electric field, increasing the breakdown voltage of semiconductor devices, achieving a desirable electrical field profile across the channel, etc.) for device 200. Additionally, by having field plate 215 covering the gate stack 213 and laterally extending from the gate stack 213, field plate 215 prevents any metal residue formation on sidewalls of the gate stack 213 from occurring.

Field plate 215 also function as a contact etch stop layer that facilitates forming a self-aligned contact opening—e.g., the source contact opening described in further detail below. Specifically, the portion of field plate 215 that extends laterally away from gate stack 213 to over source region 205 forms a contact etch stop layer that acts as a border for a later formed source contact opening (described below with respect to FIG. 2H). Also, this portion of field plate 215 extending laterally past the gate stack 213 will be connected to a subsequently formed source contact connected to the source region 205. As such, source region 205 (connected to the subsequently formed source contact) is electrically connected to field plate 215.

At step 108 of FIG. 1, a dielectric layer is formed over the field plate. As shown in FIG. 2F, a third dielectric layer 226 (e.g., a third passivation layer) is formed over second dielectric layer 208 and field plate 215. Third dielectric layer 226 may be or include silicon nitride, silicon oxide, silicon oxynitride, aluminum oxide (Al₂O₃), aluminum nitride (AlN), aluminum oxynitride (AlON), hafnium oxide (HfO₂), any other dielectric material, or a combination thereof. In some examples, third dielectric layer 226 may include the same material(s) as first dielectric layer 206 and second dielectric layer 208 such that the dielectric layers have substantially the same material composition. In other examples, third dielectric layer 226 may include different material(s) than either of first dielectric layer 206 or second dielectric layer 208 such that the one or more of the dielectric layers have substantially different material compositions from each other. Third dielectric layer 226 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example. In various examples, third dielectric layer 226 may be formed using the same or different processes than either first dielectric layer 206 and/or second dielectric layer 208. For example, third dielectric layer 226 and second dielectric layer 208 may both be formed using one or more PECVD processes and first dielectric layer 206 may be formed using one or more LPCVD processes.

At step 110 of FIG. 1, a contact trench (e.g., a contact opening) is formed through the dielectric layer to at least the III-N semiconductor layer such that the field plate is exposed in the contact trench. As shown in FIGS. 2G and 2H, a second photoresist layer 228 is patterned to form openings 230 which are used to form a source contact trench 232 and a drain contact trench 233. Referring to FIG. 2G, second photoresist layer 228 may be formed and patterned in a similar manner as first photoresist layer 222 described above. Openings 230 are formed through second photoresist layer 228 to expose portions of third dielectric layer 226 over source region 205 and drain region 207.

Referring now to FIG. 2H, a second etching process 231 is performed to form source contact trench 232 and drain contact trench 233 through portions of third dielectric layer 226, second dielectric layer 208, first dielectric layer 206, and barrier layer 204 and exposing channel layer 203 in the source region 205 and drain region 207. In some examples, the source contact trench 232 and drain contact trench 233 may extend into the channel layer 203. In various examples, the second etching process 231 may include one or more etching processes. In various examples, each of the one or more etching processes may be tuned to remove a portion of one or more of third dielectric layer 226, second dielectric layer 208, first dielectric layer 206, and barrier layer 204.

In various examples, second etching process 231 may include one or more etching processes. For example, second etching process 231 may include a main etching process and an over etching process having a high etch selectivity towards nitride-containing materials. In various examples, as described above, third dielectric layer 226, second dielectric layer 208, first dielectric layer 206, and barrier layer 204 may be formed of nitride-containing materials while field plate 215 includes metal and/or metal alloy of aluminum (Al), cobalt (Co), silicon chromium (SiCr), and/or silicon carbide chromium (SiCCr). That is, field plate 215 may be considered a nitride free layer. As such, because second etching process 231 has a high etch selectivity towards nitride-containing materials, field plate 215 (e.g. a nitride free material layer) is relatively immune from the etchant used in second etching process 231. Thus, there is little to no removal of field plate 215 during second etching process 231. Accordingly, field plate 215 advantageously provides a lower etch rate during second etching process 231 than other field plate materials which simplifies the processing and improves the quality of device 200. The lower etch rate of field plate 215 during second etching process 231 allows for removal of surrounding material layers (e.g. third dielectric layer 226, second dielectric layer 208, first dielectric layer 206, and barrier layer 204) with minimal etching of field plate 215. Moreover, because field plate 215 remains relatively unchanged after performing the second etching process 231, field plate 215 defines, in part, a self-aligned source contact opening for the subsequently formed source contact (described below with respect to a FIG. 2I).

In various examples, second etching process 231 includes a main etching process and an over etching process. In some examples, the main etching process may be a dry etch including sulfur hexafluoride (SF₆) and/or boron trichloride (BCl₃). Various parameters of the main etching process may be tuned to have a high selectivity for third dielectric layer 226, second dielectric layer 208, first dielectric layer 206, and/or barrier layer 204 over field plate 215. That is, the main etching process may be configured to etch third dielectric layer 226, second dielectric layer 208, first dielectric layer 206, and/or barrier layer 204 with little to no etching of field plate 215. For example, the various parameters may include a pressure, a top radio frequency (RF) power, a bottom RF power, an etchant gas flow, and/or a process time, among others. In various examples, the pressure may be about 5 mTorr to about 15 mTorr, and more specifically, about 8 mTorr to about 12 mTorr. In various examples, the top RF power may be about 200 W to about 300 W, and more specifically, about 225 W to about 275 W. In various examples, the bottom RF power may be about 70 W to about 110 W, and more specifically, about 80 W to about 100 W. In various examples, the flow rate of the SF₆ etchant may be about 35 sccm to about 75 sccm, and more specifically, about 45 sccm to about 65 sccm. In various examples, the flow rate of the BCl₃ etchant may be about 10 sccm to about 40 sccm, and more specifically, about 20 sccm to about 30 sccm. In various examples, the process time may be about 35 seconds to about 65 seconds, and more specifically, about 45 seconds to about 55 seconds.

In various examples, the over etching process may be a dry etch including sulfur hexafluoride (SF₆) and/or boron trichloride (BCl₃). In some examples, the parameters of the over etching process may be tuned to have a high selectivity for third dielectric layer 226, second dielectric layer 208, first dielectric layer 206, and/or barrier layer 204 over field plate 215. That is, the over etching process may be configured to etch third dielectric layer 226, second dielectric layer 208, first dielectric layer 206, and/or barrier layer 204 with little to no etching of field plate 215. The various parameters may include a pressure, a top RF power, a bottom RF power, an etchant gas flow, and/or a process time, among others. In various examples, the pressure may be about 5 mTorr to about 15 mTorr, and more specifically, about 8 mTorr to about 12 mTorr. In various examples, the top RF power may be about 200 W to about 300 W, and more specifically, about 225 W to about 275 W. In various examples, the bottom RF power may be about 35 W to about 75 W, and more specifically, about 45 W to about 65 W. In various examples, the flow rate of the SF₆ etchant may be about 35 sccm to about 75 sccm, and more specifically, about 45 sccm to about 65 sccm. In various examples, the flow rate of the BCl₃ etchant may be about 10 sccm to about 40 sccm, and more specifically, about 20 sccm to about 30 sccm. In various examples, the process time may be about 35 seconds to about 65 seconds, and more specifically, about 45 seconds to about 55 seconds.

In various examples, the main etching and over etching associated with second etching process 231 may have substantially similar process parameters. Moreover, in some examples, the main etching and over etching associated with second etching process 231 may have substantially similar process parameters except with respect to the bottom RF power. In such examples, the bottom RF power for the over etching may be less than the bottom power RF for the main etching. For example, the bottom RF power for the over etching may be about 40% less than the bottom power RF for the main etching.

As shown in FIG. 2H, second etching process 231, in various examples, may be configured to form source contact trench 232 with little to no etching of field plate 215. That is, field plate 215 may function as an etch stop layer against the one or more etching processes. Accordingly, a right-edge portion of the source contact trench 232 is defined in part by the edge of field plate 215. That is, because field plate 215 remains intact, the process disclosed herein allows for the later formed contact to be self-aligned. Additionally, while the formation of source contact trench 232 and drain contact trench 233 illustrated in FIG. 2H show little to no removal of channel layer 203, it is understood that one or more etching process can be included in method 100 to extend these contact trenches further into channel layer 203 and/or other layers of semiconductor substrate 201.

In various examples, after performing second etching process 231, an etch clean process (e.g., a wet clean process having isotropic etch characteristics) may be subsequently carried out. The etch clean process may remove by-products (e.g., polymers) produced by the one or more etching processes and formed at sidewalls of etched surfaces during the one or more etching processes. In various examples, the etch clean process may remove portions of first dielectric layer 206, second dielectric layer 208, and/or third dielectric layer 226 (e.g., to ensure thorough removal of the by-products) while preserving field plate 215. The etch clean process may be carried out after removing second photoresist layer 228 or with second photoresist layer 228 in place.

At step 112 of FIG. 1, a contact is formed in the contact trench. As shown in FIG. 2I, a source contact 234 is formed in source contact trench 232 and a drain contact 236 is formed in drain contact trench 233. In various examples, a metal layer may be formed over third dielectric layer 226, in source contact trench 232, over field plate 215, and in drain contact trench 233. Source contact 234 is electrically coupled to source region 205 and drain contact 236 is electrically coupled to drain region 207. In some examples, source contact 234 and drain contact 236 may be or include a metal, such as titanium nitride (TiN), tantalum nitride (TaN), titanium (Ti), aluminum (Al), copper (Cu), tungsten (W), the like, or a combination thereof. A patterned photoresist layer may be formed over the metal layer and one or more etching processes may be performed to remove portions of the metal layer to form source contact 234 and drain contact 236. Source contact 234 provides an electrical contact between source region 205 and field plate 215. As shown in FIG. 2I, and in various examples, source contact 234 is formed in source contact trench 232 and may extend over a portion of third dielectric layer 226 and over gate stack 213 towards drain region 207. In various examples, this extension of source contact 234 over gate stack 213 may be considered a second field plate—e.g., in addition to the field plate 215. As such, device 200 may include first and second field plates connected to each other, which in turn are connected to source contact 234. Drain contact 236 is formed within drain contact trench 233 and extends over third dielectric layer 226. As such, drain contact 236 provides an electrical contact to drain region 207. As shown in FIG. 2I, drain contact 236 is isolated from source contact 234.

After the formation of source contact 234 and drain contact 236, additional processing steps may occur to device 200. For example, an inter-layer dielectric (ILD) layer may be formed over third dielectric layer 226, source contact 234 and drain contact 236. The ILD layer may be a single dielectric layer or may include multiple dielectric layers of a same dielectric material or different dielectric materials. In various examples, the ILD layer may include silicon nitride, a silicon oxide-based material (such as a phosphosilicate glass (PSG) or a tetraethyl orthosilicate (TEOS) oxide), polytetrafluoroethylene, or the like. Additionally, respective metal vias may be formed through the ILD layer to connect to source contact 234 and drain contact 236. The metal vias may each include (i) one or more metal-barrier and/or adhesion layers (e.g., titanium nitride (TiN), tantalum nitride (TaN), the like, or a combination thereof) conformally in a respective opening through the ILD layer and (ii) a fill metal (e.g., aluminum (Al), copper (Cu), tungsten (W), the like, or a combination thereof) over and/or on the metal-barrier and/or adhesion layer(s). Also, one or more metal lines may be formed over and on (and electrically connected to) the metal vias. The metal lines may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

Although device 200 is described and shown as being an E-mode HEMT, the present disclosure is not limited to this implementation. For example, as described above, it is understood that the methods and structures disclosed herein are applicable to both E-mode HEMTs and D-mode HEMTs. That is, such self-aligned contacts can be connected to one or more field plates disposed over the gate stacks as described herein independent of the presence of gate layer 210 in the gate stack. Additionally, for example, one or more of the described self-aligned contacts can be formed as either a source contact and/or a drain contact of HEMTs (or other FETs, such as GaN FETs, silicon-based FETs, SiC-based FETs, or the like).

As described above, disclosed herein are methods of fabrication of semiconductor devices, such as HEMTs, utilizing a field plate for forming self-aligned contacts. Device 200 described above, provides field plate 215 that improves the fabrication of semiconductor devices by reducing etching and/or damage to field plate 215 that may otherwise occur during the formation of self-aligned contacts. Specifically, in various examples, by forming field plate 215 of metal and/or metal alloy having a low etch rate, such as aluminum (Al), cobalt (Co), silicon chromium (SiCr), and/or silicon carbide chromium (SiCCr), degradation of field plate 215 is minimized in the presence of etching processes that utilize etchants such as sulfur hexafluoride (SF₆) and/or boron trichloride (BCl₃). As a result, field plate 215 allows for etchants that have a high etch selectivity towards the surrounding material layers (e.g. third dielectric layer 226, second dielectric layer 208, first dielectric layer 206 and/or barrier layer 204) during the formation of contact trenches without damaging the structural and/or electrical integrity of field plate 215. Accordingly, by minimizing etching of field plate 215 during fabrication, field plate 215 may improve the function of field plate 215 as both a field plate and a contact etch stop during a self-aligned contact formation process.

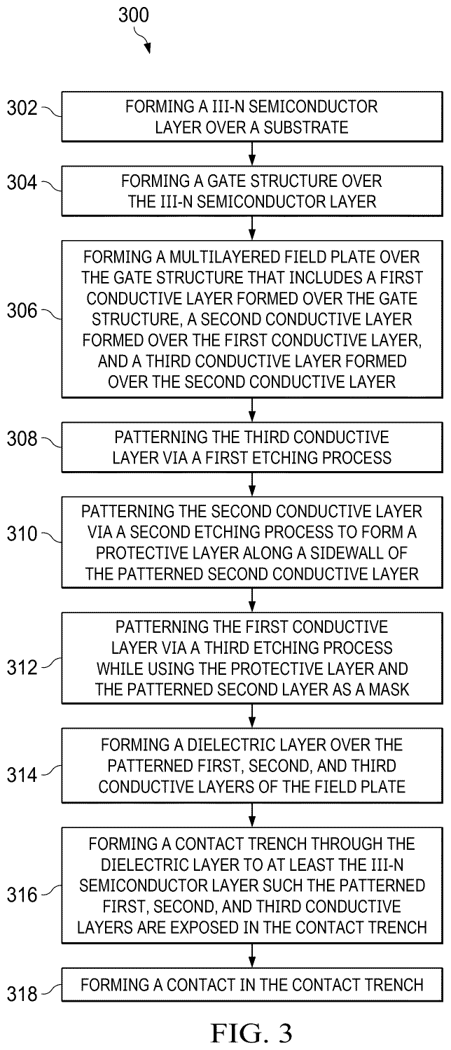

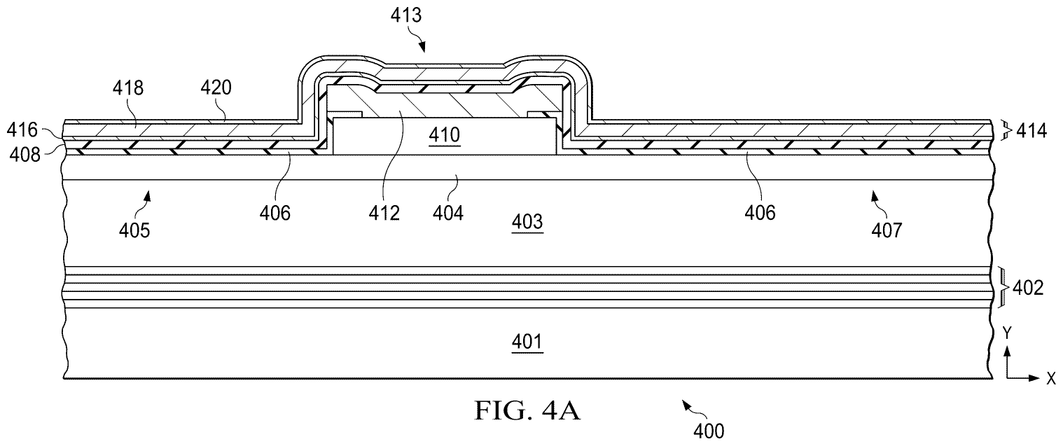

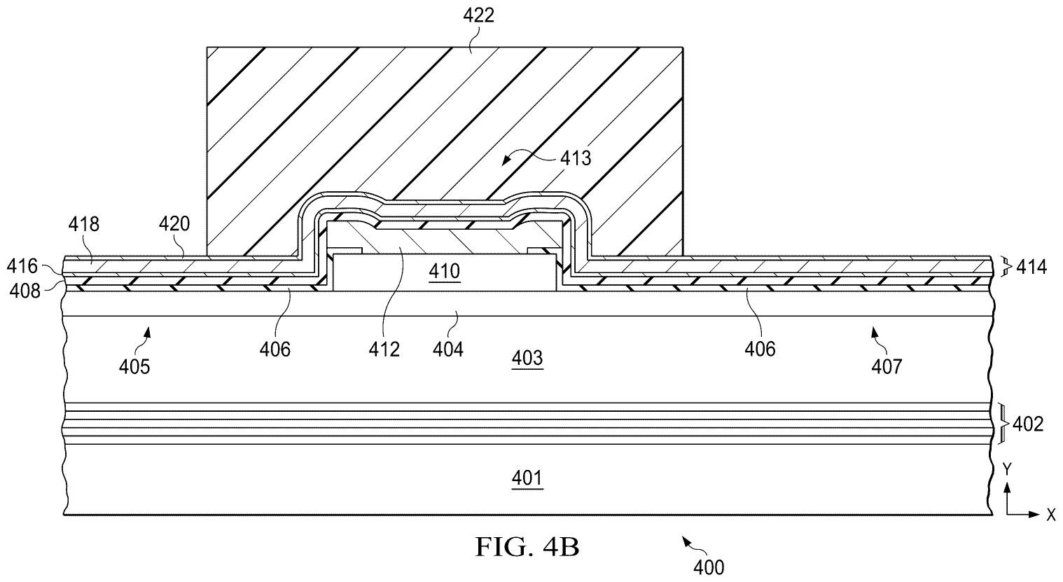

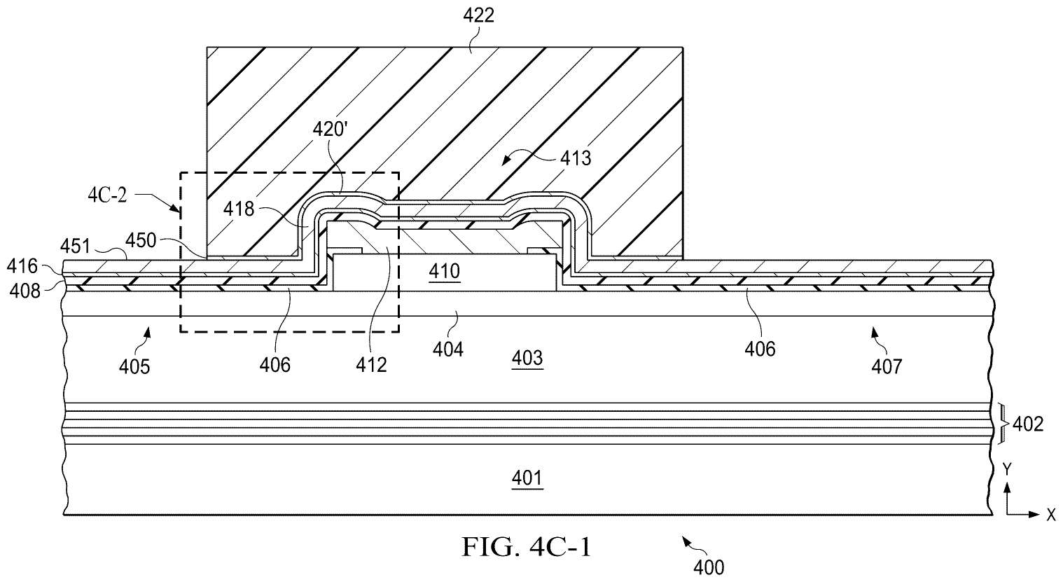

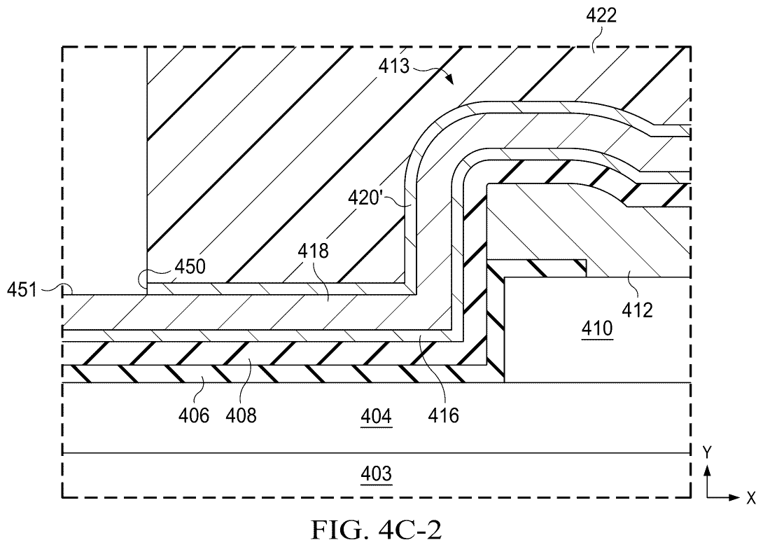

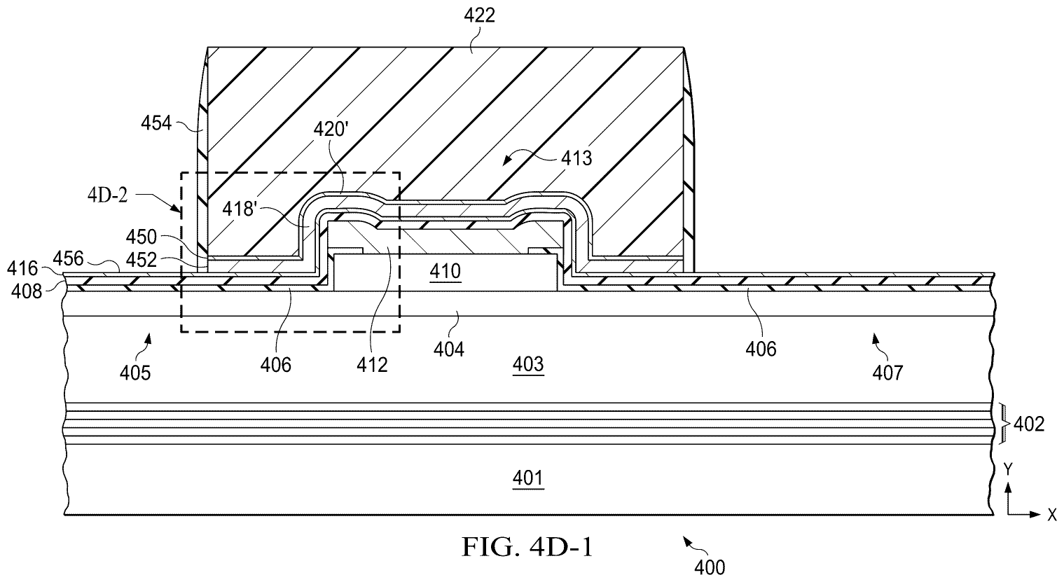

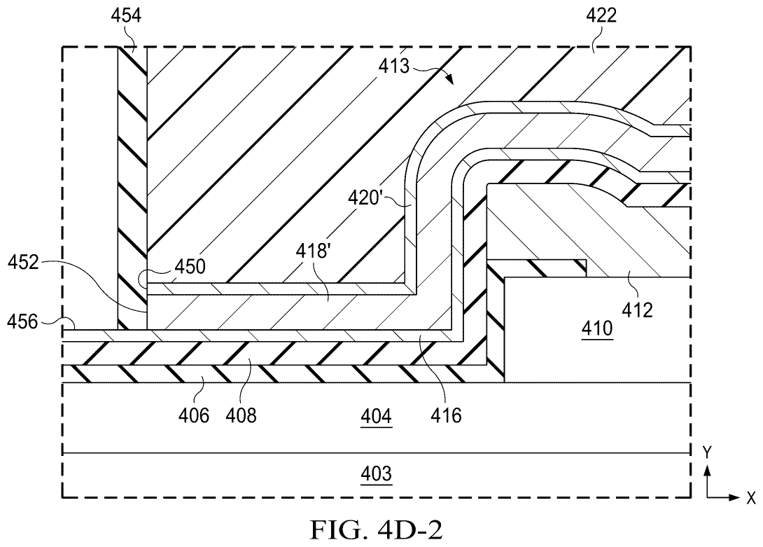

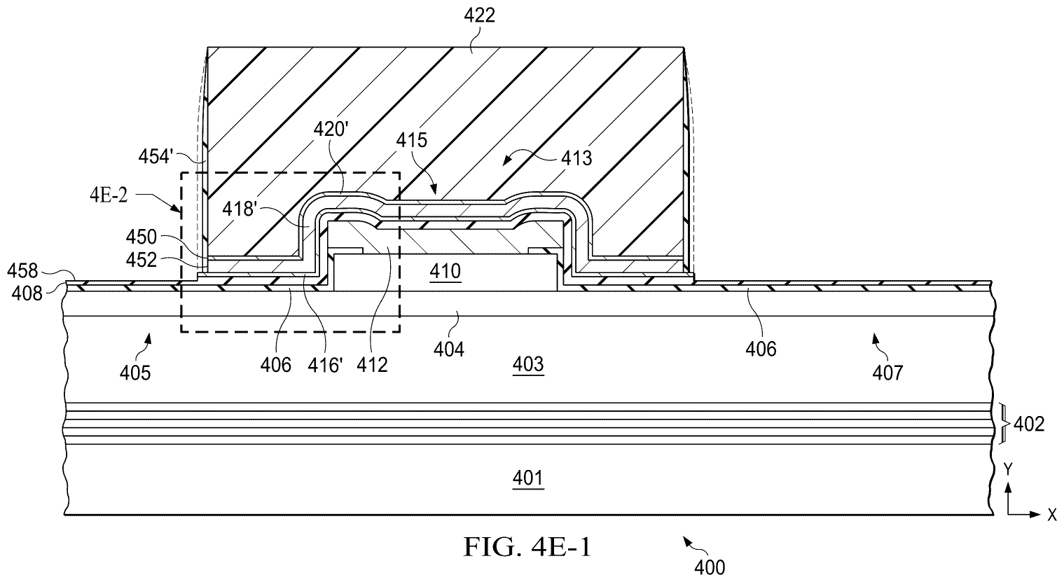

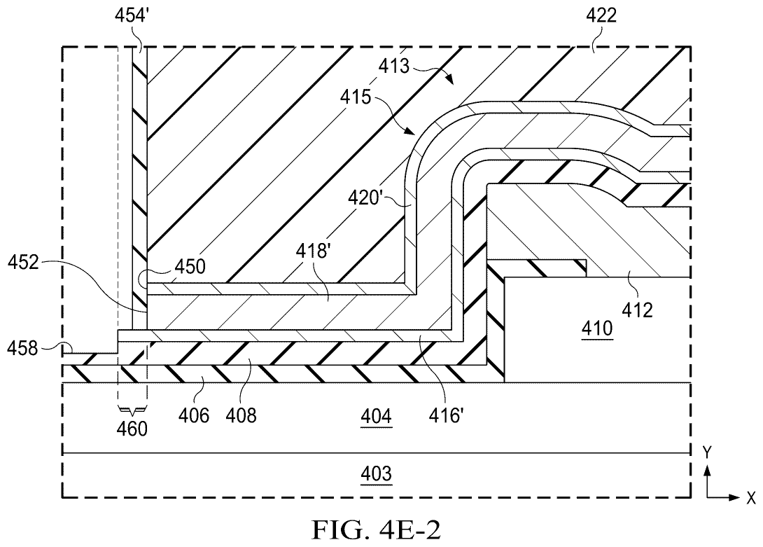

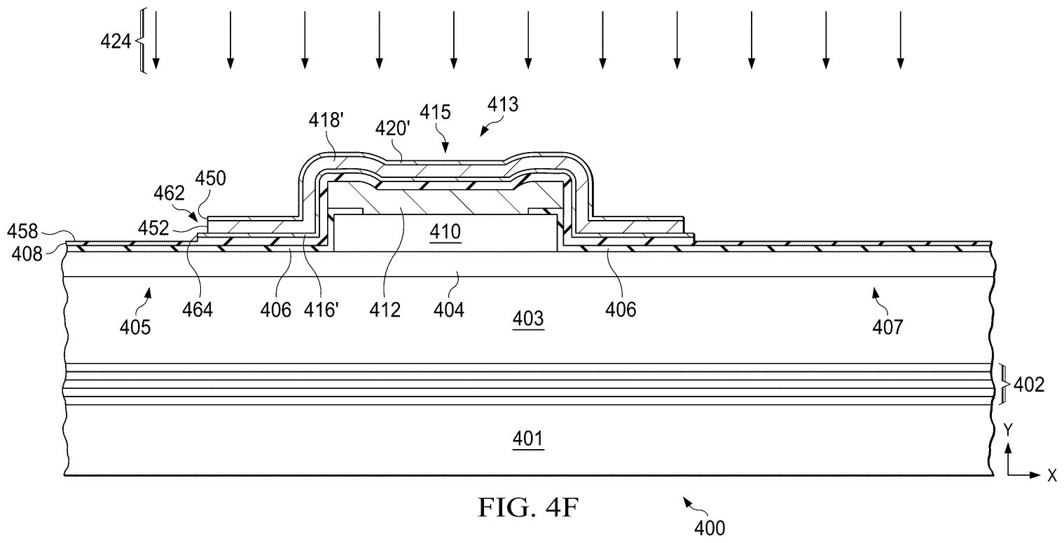

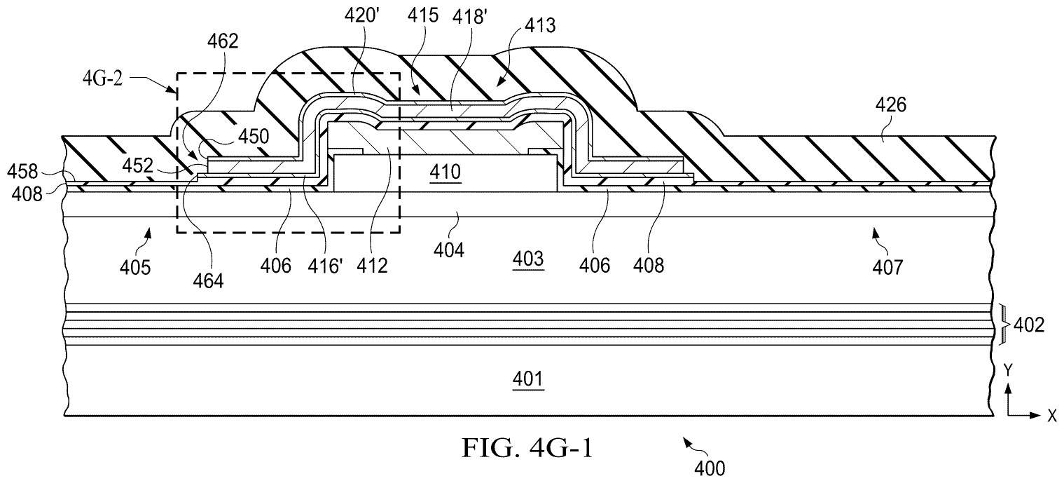

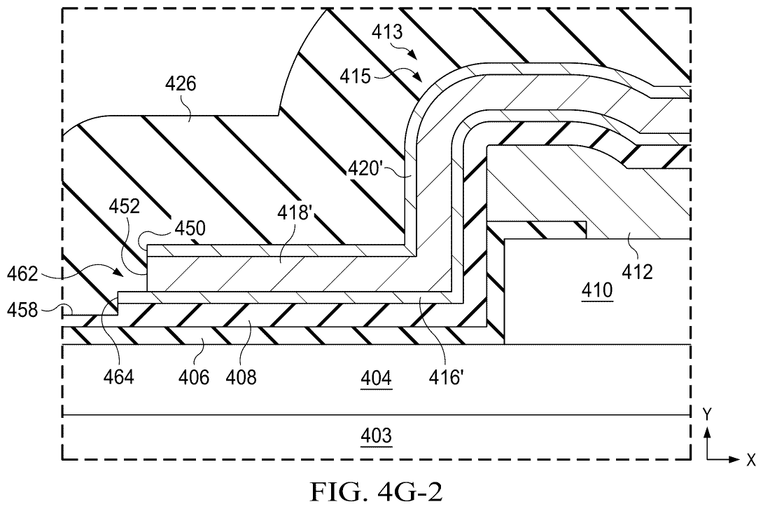

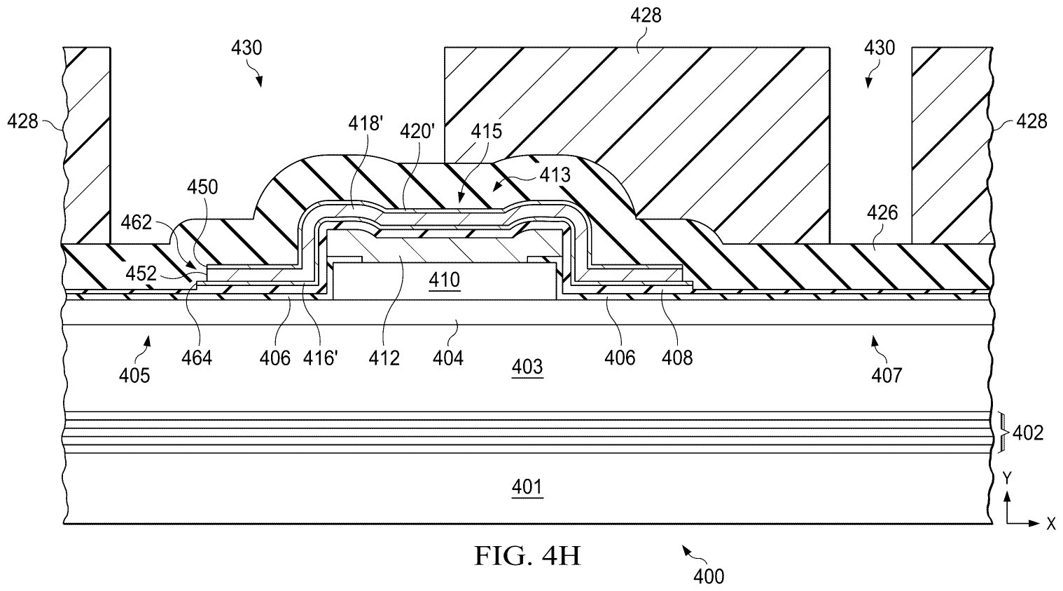

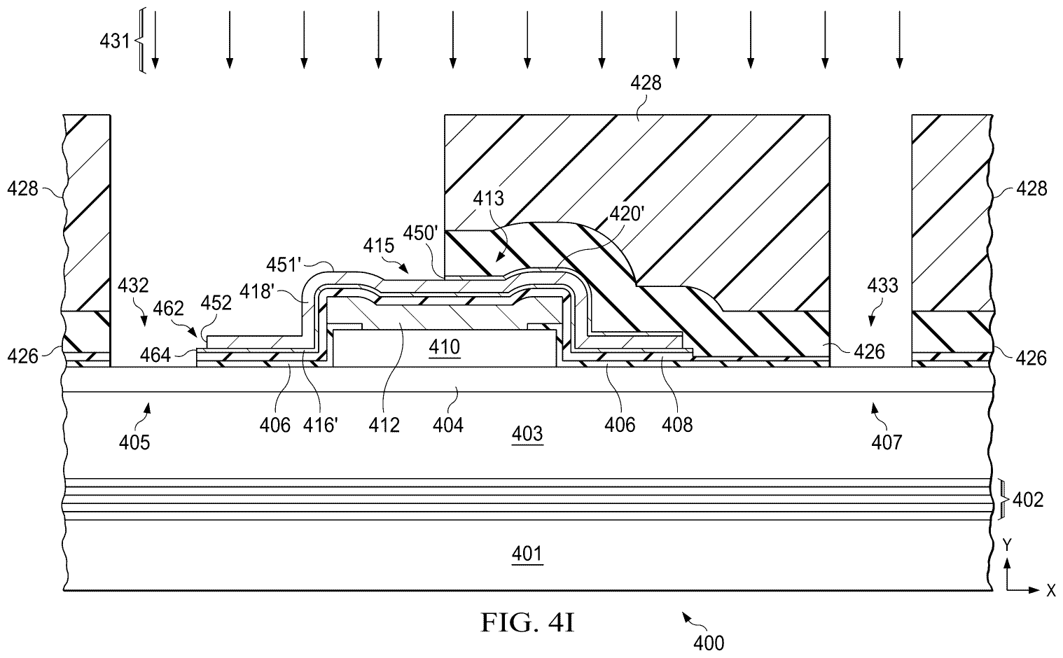

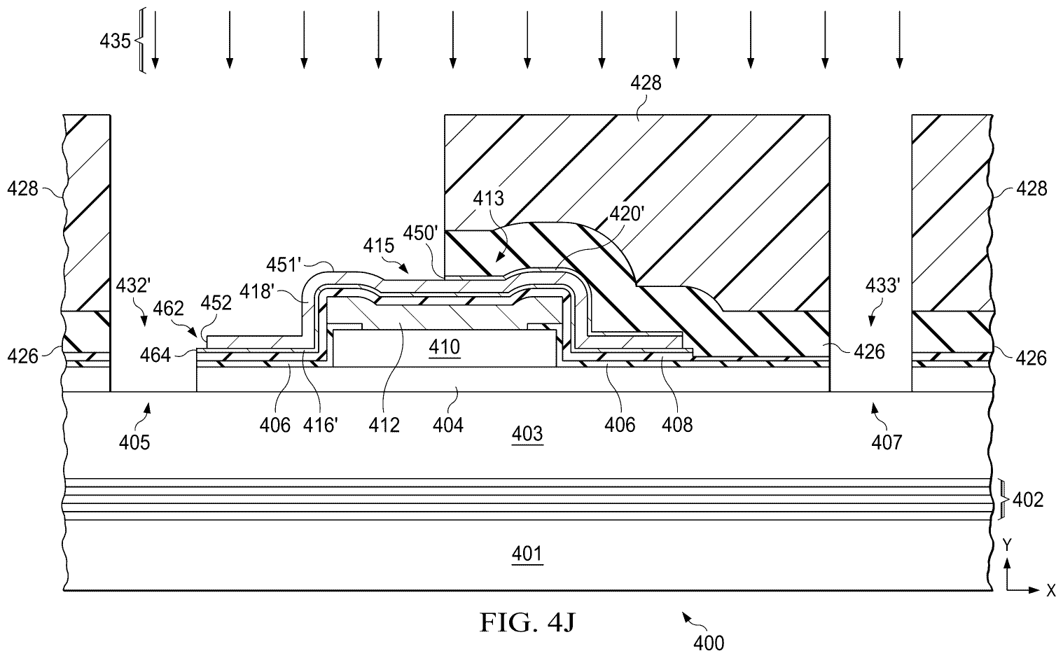

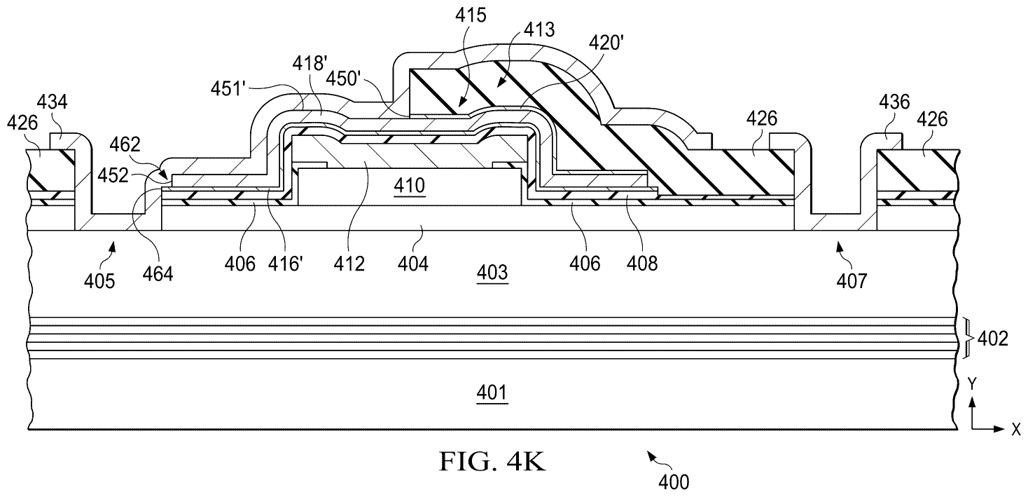

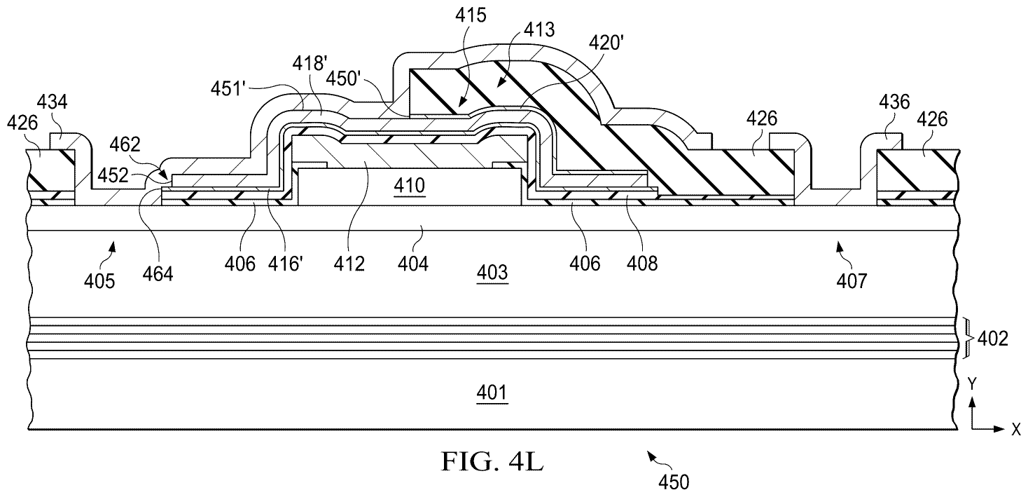

Referring now to FIG. 3, a flow diagram of a method 300 for forming a self-aligned contact using a field plate of a field effect transistor (FET) is illustrated, in accordance with various examples of the present disclosure. In various examples, method 300 may be used to form a field plate allowing for self-aligned contact openings in semiconductor devices, such as high electron mobility transistors (HEMTs). Additional processes can be provided before, during, and after method 300. As described below, method 300 is described with reference to FIGS. 4A-4L.

In that regard, FIGS. 4A-4L are diagrammatic cross-sectional views of a device 400 at various stages of fabrication (such as those associated with method 300 of FIG. 3) according to various aspects of the present disclosure. In various examples, device 400 may be a semiconductor device, such as an enhancement mode (E-mode) HEMT. Device 400 may be rated for a low voltage, a medium voltage, or a high voltage application as described above with respect to device 200. Additional features can be added to device 400, and some features described below can be replaced, modified, or eliminated in other examples of device 400. As described below, method 300 includes the formation of a multilayered field plate and the subsequent formation of a self-aligned contact.

Device 400 (e.g., as depicted in FIG. 4K) includes similar components to device 200 described above in FIGS. 2A-2I, including a semiconductor substrate 401, transition layers 402, a channel layer 403, a barrier layer 404, a source region 405, a drain region 407, a first dielectric layer 406, a second dielectric layer 408, a gate layer 410, a gate electrode 412, a gate stack 413, a third dielectric layer 426, a source contact 434, and a drain contact 436, descriptions of which may not be repeated below.

At steps 302, 304, and 306 of FIG. 3, a III-N semiconductor layer is formed over a substrate, a gate structure is formed over the III-N semiconductor layer, a multilayered field plate is formed over the gate structure that includes a first conductive layer formed over the gate structure, a second conductive layer formed over the first conductive layer, and a third conductive layer formed over the second conductive structure. As shown in FIG. 4A, device 400 includes semiconductor substrate 401, transition layers 402, channel layer 403, barrier layer 404, source region 405, drain region 407, first dielectric layer 406, second dielectric layer 408, gate layer 410, and gate electrode 412 as described above for device 200 with respect to FIG. 2A. Device 400 may be formed in a similar manner as previously described with respect to device 200.

Device 400 further includes field plate layers 414 (e.g. a multilayered field plate) that includes a first conductive layer 416, a second conductive layer 418, and a third conductive layer 420. First conductive layer 416 is formed over second dielectric layer 408, second conductive layer 418 is formed over first conductive layer 416, and third conductive layer 420 is formed over second conductive layer 418. In some examples, field plate layers 414 may include first conductive layer 416 and second conductive layer 418 and not include third conductive layer 420. The following descriptions will be directed to field plate layers 414 including the three conductive layers. However, it should be understood that the process for using two conductive layers (or more than three conductive layers) in field plate layers 414 is similar and is within the scope of this disclosure.

In various examples, first conductive layer 416 (e.g. first metal layer) includes a metal, or metal alloy such as, for example, titanium (Ti), titanium tungsten (TiW), or titanium nitride (TiN), among others. In various examples, first conductive layer 416 may be deposited using a physical vapor deposition (PVD) deposition, a sputtering deposition, or other suitable process techniques. In various examples, first conductive layer 416 may have a thickness of about 10 nm to about 500 nm, and more specifically, about 50 nm to about 400 nm. In various example, the thickness of first conductive layer 416 may be larger or smaller depending on the desired application.

In various examples, second conductive layer 418 (e.g. second metal layer) includes a metal or metal alloy of aluminum (Al), cobalt (Co), silicon chromium (SiCr), and/or silicon carbide chromium (SiCCr), among others. In some examples, second conductive layer 418 is or includes aluminum copper (AlCu). In various examples, second conductive layer 418 may be deposited over and on first conductive layer 416 using a PVD deposition, a sputtering deposition, or other suitable process techniques. In various examples, second conductive layer 418 may be deposited in the absence of argon (Ar) (e.g., without backside Ar gas during deposition) and at a temperature of less than 100° C., and more specifically, less than 80° C. Such deposition parameters reduce surface roughness of the deposited layer including examples using aluminum. Reducing the surface roughness of the deposited aluminum (e.g., second conductive layer 418) tends to reduce blistering (or peeling) of second conductive layer 418 on first conductive layer 416 and improve adhesion of third conductive layer 420 on second conductive layer 418. In various examples, second conductive layer 418 may have a thickness of about 30 nm to about 800 nm, and more specifically, about 100 nm to about 600 nm. In various examples, the thickness of first conductive layer 416 is about 5% to about 70% of the thickness of second conductive layer 418, and more specifically about 10% to about 60% the thickness of second conductive layer 418. In various examples, the ratio of the thickness of first conductive layer 416 to the thickness of second conductive layer 418 may be tuned to avoid blistering of field plate 415.

In various examples, third conductive layer 420 (e.g. third metal layer) includes a metal or metal alloy such as, for example, titanium (Ti), titanium tungsten (TiW), or titanium nitride (TiN), among others. In various examples, third conductive layer 420 may be deposited over and on second conductive layer 418 using a PVD deposition, a sputtering deposition, or other suitable process techniques. In various examples, third conductive layer 420 may have a thickness of about 10 nm to about 500 nm, and more specifically, about 50 nm to about 400 nm. In various example, the thickness of third conductive layer 420 may be larger or smaller depending on the desired application. As shown, third conductive layer 420 is thinner than second conductive layer 418 and has a substantially similar thickness to first conductive layer 416. As mentioned above and in various examples, third conductive layer 420 may be omitted from field plate layers 414. Third conductive layer 420 may be used as a hard mask layer and may be omitted depending on the desired application and manufacturing processes used.

In various examples, a high temperature annealing process may be performed after forming first conductive layer 416, second conductive layer 418, and third conductive layer 420. In various examples in which third conductive layer 420 is omitted, the high temperature annealing process may be performed after forming first conductive layer 416 and second conductive layer 418. In various examples, the high temperature annealing process may include nitrogen (N₂) and occur at a temperature of about 550° C. to about 800° C. In various other examples, an annealing process may be performed during deposition of one or more of first, second, or third conductive layer 416, 418, 420. In some examples, this process may include N₂ or Ar gas and may occur at a temperature less than about 500° C. The high temperature annealing process tends to reduce and/or eliminate peeling (or blistering) of second conductive layer 418 from first conductive layer 416.

Accordingly, as described above, first, second, and third conductive layers 416, 418, and 420 may be formed of various conductive materials including metals and alloys thereof. Additionally, in some examples, first, second, and/or third conductive layers 416, 418, and 420 have a different material composition from each other. For the purpose of clarity in the following description, method 300 proceeds in examples where first conductive layer 416, second conductive layer 418, and third conductive layer have different material compositions from each other.

At step 308 of FIG. 3, the third conductive layer is patterned via a first etching process. As shown in FIGS. 4B, 4C-1, and 4C-2, a patterned first photoresist layer 422 is formed over field plate layers 414 and third conductive layer 420 is etched using first photoresist layer 422 as a mask to form patterned third conductive layer 420′. In various examples in which third conductive layer 420 is omitted from device 400, step 308 and the first etching process may be omitted. First photoresist layer 422 may be formed and patterned in a similar manner as described above with respect to first photoresist layer 222 in FIG. 2C.

Referring now to FIGS. 4C-1 and 4C-2, a first etching process is performed to remove portions of third conductive layer 420 not covered by first photoresist layer 422 to form patterned third conductive layer 420′. The first etching process exposes sidewalls 450 of third conductive layer 420 and a top surface 451 of second conductive layer 418. In various examples, the first etching process may include one or more etching processes. In various examples, the one or more etching processes may be a wet etch process, a dry etch process, or combinations thereof. The one or more processes may be tuned to remove third conductive layer 420 with little to no etching of second conductive layer 418. Different parameters of the first etching process may be tuned for the desired application, including an etchant type, an etchant flow rate, a chamber pressure, a transformer coupled plasma (TCP) radio frequency (RF) power, a bias RF power, and a process time. In various examples, the etchant may be sulfur hexafluoride (SF₆) and/or boron trichloride (BCl₃). In various examples, the flow rate of the SF₆ etchant may be about 20 sccm to about 50 sccm, and more specifically, about 30 sccm to about 40 sccm. In various examples the flow rate of the BCl₃ etchant may be about 30 sccm to about 60 sccm, and more specifically, about 40 sccm to about 50 sccm. In various examples, the chamber pressure may be about 5 mTorr to about 25 mTorr, and more specifically, about 10 mTorr to about 20 mTorr. In various examples, the TCP RF power may be about 250 W to about 450 W, and more specifically, about 325 W to about 375 W. In various examples, the bias RF power may be about 200 W to about 350 W, and more specifically, about 250 W to about 280 W. In various examples, the process time may be about 5 seconds to about 25 seconds, and more specifically, about 10 seconds to about 15 seconds.

At step 310 of FIG. 3, the second conductive layer is patterned via a second etching process to form a protective layer along sidewall of the patterned second conductive layer. As shown in FIGS. 4D-1 and 4D-2, a second etching process is performed to remove portions of second conductive layer 418 not covered by first photoresist layer 422 to form patterned second conductive layer 418′. The second etching process exposes a top surface 456 of first conductive layer 416. Also, the second etch process causes a protective layer 454 to form along and on sidewalls of first photoresist layer 422, along and on sidewalls 452 of patterned second conductive layer 418′, and along and on sidewalls 450 of patterned third conductive layer 420′. In various examples, protective layer 454 may be a polymer by-product of the second etching process. In various examples, protective layer 454 may be a metal or metal alloy-containing polymer. For example, when second conducive layer 418 includes aluminum the protective layer 454 may include an aluminum-containing polymer. As described below, protective layer 454 may be used as an etching mask in later processing steps which also protects the patterned second conductive layer 418′ during those later process steps.

In various examples, the second etching process may include one or more etching processes. In various examples, the one or more etching processes may be a wet etch process, a dry etch process, or combinations thereof. The one or more processes may be tuned to remove second conductive layer 418 with little to no etching of first conductive layer 416. Different parameters of the second etching process may be tuned for the desired application, including an etchant type, an etchant flow rate, a chamber pressure, an RF power, a bias RF power, and a process time. In various examples, the etchant may be boron trichloride (BCl₃) and/or chlorine (Cl₂). In various examples the flow rate of the BCl₃ etchant may be about 30 sccm to about 70 sccm, and more specifically, about 45 sccm to about 55 sccm. In various examples, the flow rate of the Cl₂ etchant may be about 5 sccm to about 35 sccm, and more specifically, about 15 sccm to about 25 sccm. In various examples, the chamber pressure may be about 5 mTorr to about 25 mTorr, and more specifically, about 10 mTorr to about 20 mTorr. In various examples, the RF power may be about 350 W to about 550 W, and more specifically, about 425 W to about 475 W. In various examples, the bias RF power may be about 350 W to about 550 W, and more specifically, about 420 W to about 470 W. In various examples, the process time may be about 15 seconds to about 45 seconds, and more specifically, about 24 seconds to about 32 seconds.

At step 312 of FIG. 3, the first conductive layer is patterned via a third etching process while using the photoresist layer, the protective layer, and the patterned second conductive layer as a mask. As shown in FIGS. 4E-1 and 4E-2, a third etching process is performed to remove portions of first conductive layer 416 not covered by both first photoresist layer 422 and protective layer 454 to form patterned first conductive layer 416′. The third etching process exposes a top surface 458 of second dielectric layer 408 and removes a portion of protective layer 454 from the sidewalls of first photoresist layer 422, sidewalls 452 of patterned second conductive layer 418′, and sidewalls 450 of patterned third conductive layer 420′. An etched protective layer 454′ remains along and on the sidewalls of first photoresist layer 422, the sidewalls 452 of patterned second conductive layer 418′, and sidewalls 450 of patterned third conductive layer 420′. The remaining etched protective layer 454′ protects first photoresist layer 422, patterned third conductive layer 420′, and patterned second conductive layer 418′ from the third etching process. As shown, after the etching of first conductive layer a portion 460 of the patterned first conductive layer 416′ extends laterally (e.g. in the x-direction) further over semiconductor substrate 201 than either of patterned second conductive layer 418′ or patterned third conductive layer 420′.

In various examples, the third etching process may include one or more etching processes. In various examples, the one or more etching processes may be a wet etch process, a dry etch process, or combinations thereof. The one or more processes may be tuned to remove first conductive layer 416 with little to no etching of second dielectric layer 408. Different parameters of the third etching process may be tuned for the desired application, including an etchant type, an etchant flow rate, a chamber pressure, an RF power, a bias RF power, and a process time. In various examples, the etchant may be boron trichloride (BCl₃) and/or chlorine (Cl₂). In various examples the flow rate of the BCl₃ etchant may be about 30 sccm to about 70 sccm, and more specifically, about 45 sccm to about 55 sccm. In various examples, the flow rate of the Cl₂ etchant may be about 5 sccm to about 35 sccm, and more specifically, about 15 sccm to about 25 sccm. In various examples, the chamber pressure may be about 5 mTorr to about 25 mTorr, and more specifically, about 10 mTorr to about 20 mTorr. In various examples, the RF power may be about 350 W to about 550 W, and more specifically, about 425 W to about 475 W. In various examples, the bias RF power may be about 50 W to about 150 W, and more specifically, about 75 W to about 125 W. In various examples, the process time may be about 4 seconds to about 15 seconds, and more specifically, about 7 seconds to about 12 seconds.

Next, as shown in FIG. 4F, a removal process 424 is performed to remove the remaining etched protective layer 454′ and first photoresist layer 422 from over semiconductor substrate 201. In various examples, removal process 424 may include one or more etching processes. In various examples, the one or more etching processes may include a wet etch process, a dry etch process, or a combination thereof. In some examples, removal process 424 may include a plasma ashing process.

As shown in FIG. 4F, patterned first conductive layer 416′, patterned second conductive layer 418′, and patterned third conductive layer 420′ form field plate 415. As shown, field plate 415 has a stepped (or staggered) edge profile edge 462. This stepped profile edge is a structural characteristic of the patterning process described above. Specifically, because protective layer 454′ remains disposed along sidewalls of the patterned third conductive layer and second conductive layer during the etching of the first conductive layer this causes the patterned first conductive layer 416′ to have a sidewall 464 that is offset from sidewall 452 of the patterned second conductive layer 418′ and a sidewall 450 of patterned third conductive layer 420′. As such, patterned first conductive layer 416′ extends laterally (e.g. in the x-direction) further over semiconductor substrate 201 than either of patterned second conductive layer 418′ or patterned third conductive layer 420′. It is understood in examples that omit third conductive layer 420, this stepped profile would be present between patterned second conductive layer 418′ and patterned first conductive layer 416′ as protective layer 454′ would remain disposed along sidewall 452 of patterned second conductive layer 418′ during the etching of first conductive layer 416 which would cause patterned first conductive layer 416′ to have sidewall 464 that is offset from sidewall 452 of patterned second conductive layers 418′.

At step 314 of FIG. 3, a dielectric layer is formed over the patterned first, second, and third conductive layers of the field plate. Referring now to FIGS. 4G-1 and 4G-2, third dielectric layer 426 is formed over field plate 415, including on patterned first conductive layer 416′, patterned second conductive layer 418′, and patterned third conductive layer 420′. Third dielectric layer 426 may be formed similar to the process described above with respect to third dielectric layer 226 in FIG. 2F.

At step 316 of FIG. 3, a contact trench (e.g., a contact opening) is formed through the dielectric layer to at least the III-N semiconductor layer such that the patterned first, second, and third conductive layers are exposed in the contact trench. As shown in FIGS. 4H, 4I, and 4J, a second photoresist layer 428 is formed on device 400 and patterned to form openings 430 through which a source contact trench 432 and a drain contact trench 433 are formed. Referring now to FIG. 4H, second photoresist layer 428 may be formed and patterned in a similar manner as first photoresist layer 422 described above. Openings 430 are formed through second photoresist layer 428 to expose portions of third dielectric layer 426 over source region 405 and drain region 407.

Referring now to FIG. 4I, a fourth etching process 431 is performed to form source contact trench 432 and drain contact trench 433 in a process similar to the forming of source contact trench 232 and drain contact trench 233 described above in FIG. 2H. Fourth etching process 431 forms source contact trench 432 and drain contact trench 433 through portions of third dielectric layer 426, second dielectric layer 408, and first dielectric layer 406, exposing portions of barrier layer 404 over source region 405 and drain region 407. Fourth etching process 431 further removes a portion of patterned third conductive layer 420′ that is not protected by third dielectric layer 426 and exposes a top surface 451′ of patterned second conductive layer 418′ and a sidewall 450′ of patterned third conductive layer 420′.

In various examples, fourth etching process 431 may include one or more etching processes. In various examples, fourth etching process 431 includes one or more etching processes to remove a portion of one or more of third dielectric layer 426, second dielectric layer 408, first dielectric layer 406, and barrier layer 404. In various examples, the one or more etching processes may include a wet etch, a dry etch, or a combination thereof. In various examples, the one or more etching processes may include an etching process similar to second etching process 231 described above with respect to FIG. 2H as well as the various parameters associated with each etching process such as pressure, top radio frequency (RF) power, bias RF power (or bottom RF power), etchant gas flow, and/or process time. In some examples, the one or more etching processes may include sulfur hexafluoride (SF₆) and boron trichloride (BCl₃). In some examples, the SF₆ may be used as the etchant and the BCl₃ may be an additive gas to control the shape of source contact trench 432 and drain contact trench 433. In various examples, the flow rate of the SF₆ etchant may be about 45 sccm to about 65 sccm, and more specifically about 50 sccm to about 60 sccm. In various examples, the flow rate of the BCl₃ gas may be about 15 sccm to about 35 sccm, and more specifically, about 20 sccm to about 30 sccm. In various examples, the pressure may be about 5 mTorr to about 15 mTorr, and mores specifically, about 8 mTorr to about 12 mTorr. In various examples, the top RF power may be about 200 W to about 300 W, and more specifically, about 225 W to about 275 W. In various examples, the bias RF power may be about 35 W to about 125 W, and more specifically, about 50 W to about 100 W. In various examples, the process time may be about 35 seconds to about 90 seconds, and more specifically, about 50 seconds to about 70 seconds.

As shown, patterned second conductive layer 418′ of field plate 415 remains relatively unetched after preforming fourth etching process 431. This is because fourth etching process 431 has a high etch selectivity toward the materials of third dielectric layer 426, second dielectric layer 408, and first dielectric layer 406 relative to the material of patterned second conductive layer 418′ of field plate 415. Moreover, patterned second conductive layer 418′ protects the underlying patterned first conductive layer 416′ from being etched during fourth etching process 431 by acting as an etch stop layer. Thus, while the exposed portions of patterned third conductive layer 420′ may be etched through during fourth etching process 431, patterned second conductive layer 418′ (and patterned first conductive layer 416′ disposed thereunder) of field plate 415 remain relatively unetched through fourth etching process 431. Accordingly, patterned second conductive layer 418′ of field plate 415 advantageously provides a lower etch rate during this etching process than other field plate materials which simplifies the processing and improves the quality of device 400. The lower etch rate of patterned second conductive layer 418′ of field plate 415 during fourth etching process 431 allows for removal of surrounding material layers (e.g. third dielectric layer 426, second dielectric layer 408, and first dielectric layer 406) with minimal etching of patterned second conductive layer 418′ of field plate 415. Moreover, because patterned second conductive layer 418′ (and patterned first conductive layer 416′ disposed thereunder) of field plate 415 remains relatively unchanged after performing fourth etching process 431 this layer of field plate 415 defines, in part, a self-aligned source contact opening for the subsequently formed source contact.

Referring now to FIG. 4J, an optional fifth etching process 435 may be performed. Specifically, fifth etching process 435 may etch through the exposed portions of barrier layer 404 in source contact trench 432 and drain contact trench 433 to expose portions of channel layer 403 to form an extended source contact trench 432′ and an extended drain contact trench 433′, respectively. In various other examples, source contact trench 432′ and drain contact trench 433′ may extend into channel layer 403. In various examples, fifth etching process 435 may include one or more etching processes. In various examples, the one or more etching processes may include a wet etch, a dry etch, or a combination thereof. In various examples, the one or more etching processes may include various parameters associated with each etching process such as pressure, top radio frequency (RF) power, bias RF power, etchant gas flow, and/or process time. In some examples, the one or more etching process may include chlorine (CL₂) and boron trichloride (BCl₃). In various examples, the flow rate of the Cl₂ etchant may be about 60 sccm to about 100 sccm, and more specifically about 70 sccm to about 90 sccm. In various examples, the flow rate of the BCl₃ gas may be about 10 sccm to about 30 sccm, and more specifically, about 15 sccm to about 25 sccm. In various examples, the pressure may be about 5 mTorr to about 15 mTorr, and mores specifically, about 8 mTorr to about 12 mTorr. In various examples, the top RF power may be about 200 W to about 300 W, and more specifically, about 225 W to about 275 W. In various examples, the bias RF power may be about 20 W to about 50 W, and more specifically, about 30 W to about 40 W. In various examples, the process time may be about 2 seconds to about 15 seconds, and more specifically, about 4 seconds to about 10 seconds.

Additionally, a removal process may be performed to remove second photoresist layer 428. In various examples, the removal process may include one or more removal processes. In some examples, the one or more removal processes may include a plasma ashing process.

At step 318, a contact is formed in the contact trench. As shown in FIG. 4K, source contact 434 is formed in source contact trench 432′ and drain contact 436 is formed in drain contact trench 433′. The process of forming source contact 434 and drain contact 436 is similar to the process of forming source contact 234 and drain contact 236 described above in FIG. 2I.

Referring now to FIG. 4L, an alternative device 450 is shown. Alternative device 450 is similar to device 400 and may be manufactured using the processes described above for device 400. Alternative device 450 omits fifth etching process 435 described above in FIG. 4J that etches through barrier layer 404. Source contact 434 and drain contact 436 are subsequently formed in source contact trench 432 and drain contact trench 433, respectively. As shown, source contact 434 and drain contact 436 extend to barrier layer 404 without extending to channel layer 403 because portions of barrier layer 404 remain disposed between channel layer 403 and source contact 434 and drain contact 436 as a result of fifth etching process 435 being omitted.

After the formation of source contact 434 and drain contact 436, additional processing steps may occur to device 400. For example, an inter-layer dielectric layer (ILD) may be formed over third dielectric layer 426, source contact 434 and drain contact 436. The ILD layer may be a single dielectric layer or may include multiple dielectric layers of a same dielectric material or different dielectric materials. In various examples, the ILD layer may include silicon nitride, a silicon oxide-based material (such as a phosphosilicate glass (PSG) or a tetraethyl orthosilicate (TEOS) oxide), polytetrafluoroethylene, or the like. Additionally, respective metal vias may be formed through the ILD layer to connect to source contact 434 and drain contact 436. The metal vias may each include (i) one or more metal-barrier and/or adhesion layers (e.g., titanium nitride (TiN), tantalum nitride (TaN), the like, or a combination thereof) conformally in a respective opening through the ILD layer and (ii) a fill metal (e.g., aluminum (Al), copper (Cu), tungsten (W), the like, or a combination thereof) over and/or on the metal-barrier and/or adhesion layer(s). Also, one or more metal lines may be formed over and on (and electrically connected to) the metal vias. The metal lines may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

Although devices 400 and 450 are described and shown as being an E-mode HEMT, the present disclosure is not limited to this implementation. For example, as described above, it is understood that the methods and structures disclosed herein are applicable to both E-mode HEMTs and D-mode HEMTs. That is, such self-aligned contacts can be connected to one or more field plates disposed over the gate stacks as described herein independent of the presence of gate layer 410 in the gate stack. Additionally, for example, one or more of the described self-aligned contacts can be formed as either a source contact and/or a drain contact of HEMTs (or other FETs, such as GaN FETs, silicon-based FETs, SiC-based FETs, or the like).

As described above, disclosed herein are methods of fabrication of semiconductor devices, such as HEMTs, utilizing a field plate for forming self-aligned contacts. Devices 400 and 450 described above, provide a multilayered field plate (e.g. field plate 415) that improves the fabrication of semiconductor devices by reducing etching and/or damage to field plate 415 that may otherwise occur during the formation of self-aligned contacts. Multilayered field plate 415 (e.g., patterned second conductive layer 418′) allows for etchants that have a high etch selectivity towards the surrounding material layers (e.g. third dielectric layer 426, second dielectric layer 408, first dielectric layer 406 and/or barrier layer 404) during the formation of contact trenches without damaging the structural and/or electrical integrity of field plate 415. By minimizing etching of field plate 415 (e.g., patterned second conductive layer 418′) during fabrication, field plate 415 may improve the function of field plate 415 as both a field plate and a contact etch stop during a self-aligned contact formation process.

Additionally, the fabrication of field plate 415 as having multiple layers reduces film peeling and/or blistering between the layers of the field plate. Specifically, as described above, second conductive layer 418 includes a metal or metal alloy such as aluminum or an aluminum alloy that may be deposited in the absence of argon (Ar) (e.g., without backside Ar gas during deposition) and at a temperature of less than 100° C., and more specifically, less than 80° C. Such deposition parameters reduce surface roughness of the deposited aluminum. Reducing the surface roughness of the deposited aluminum (e.g., second conductive layer 418) tends to reduce blistering of second conductive layer 418 on first conductive layer 416 and improve adhesion of third conductive layer 420 on second conductive layer 418.

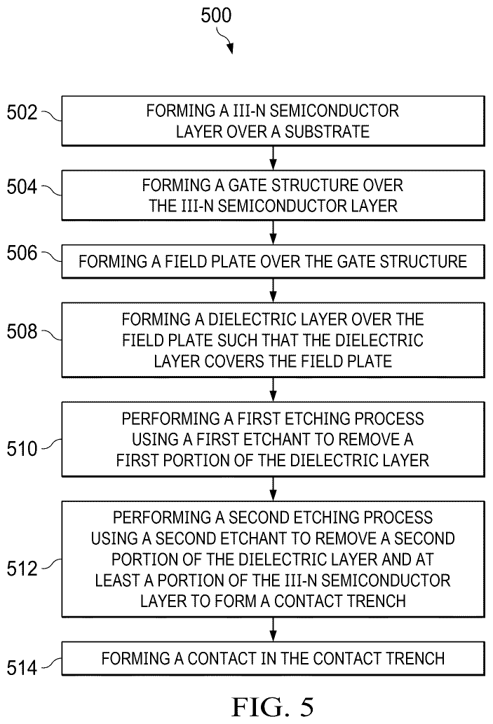

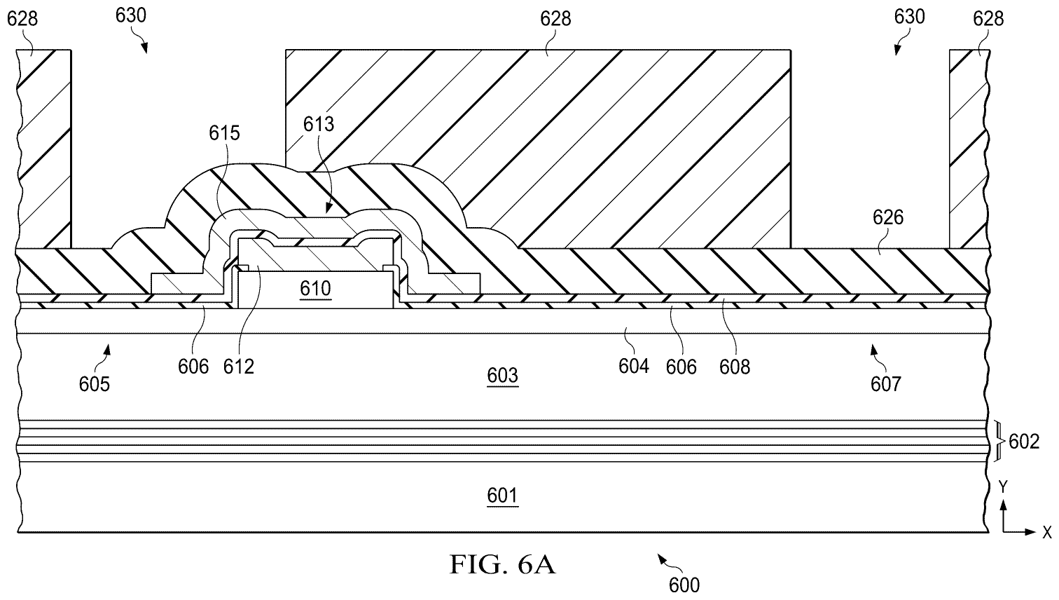

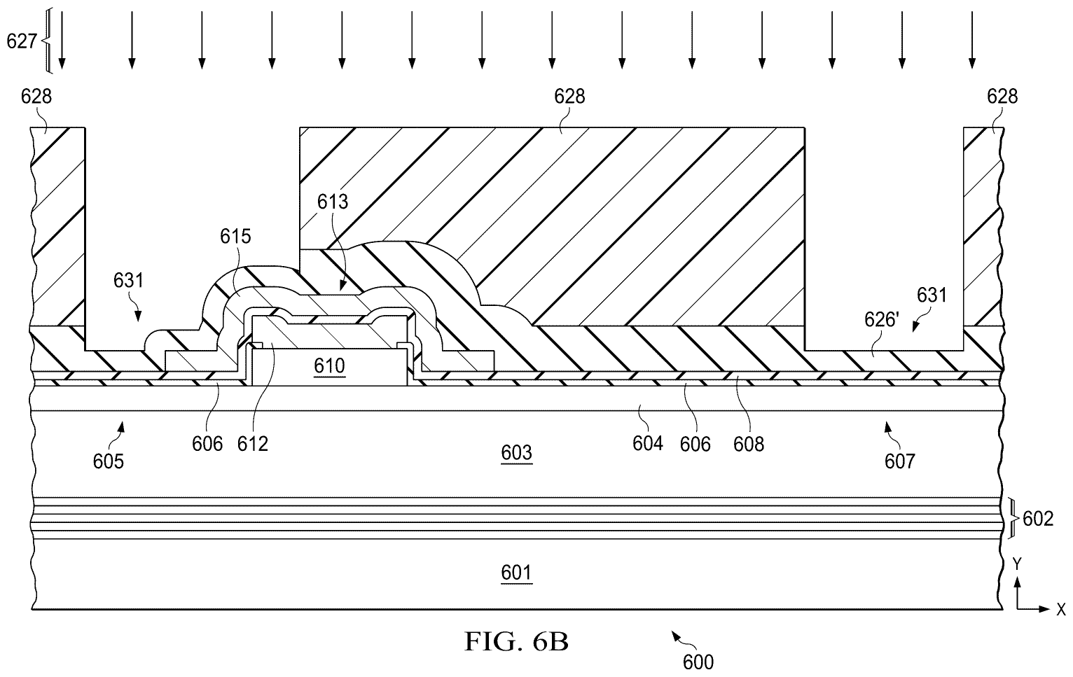

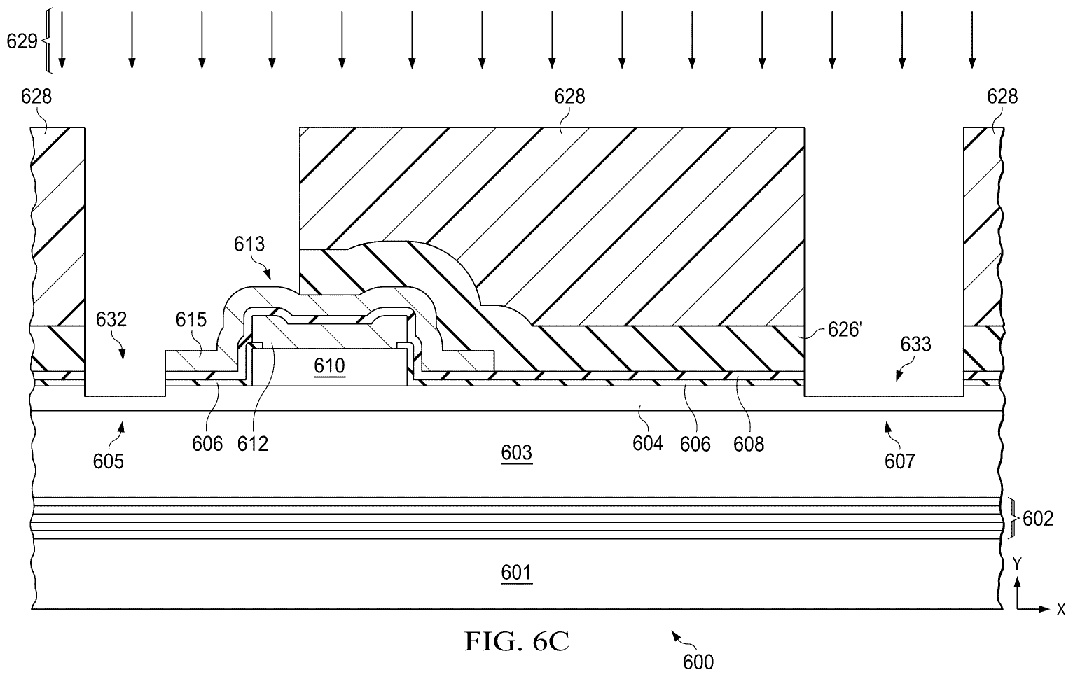

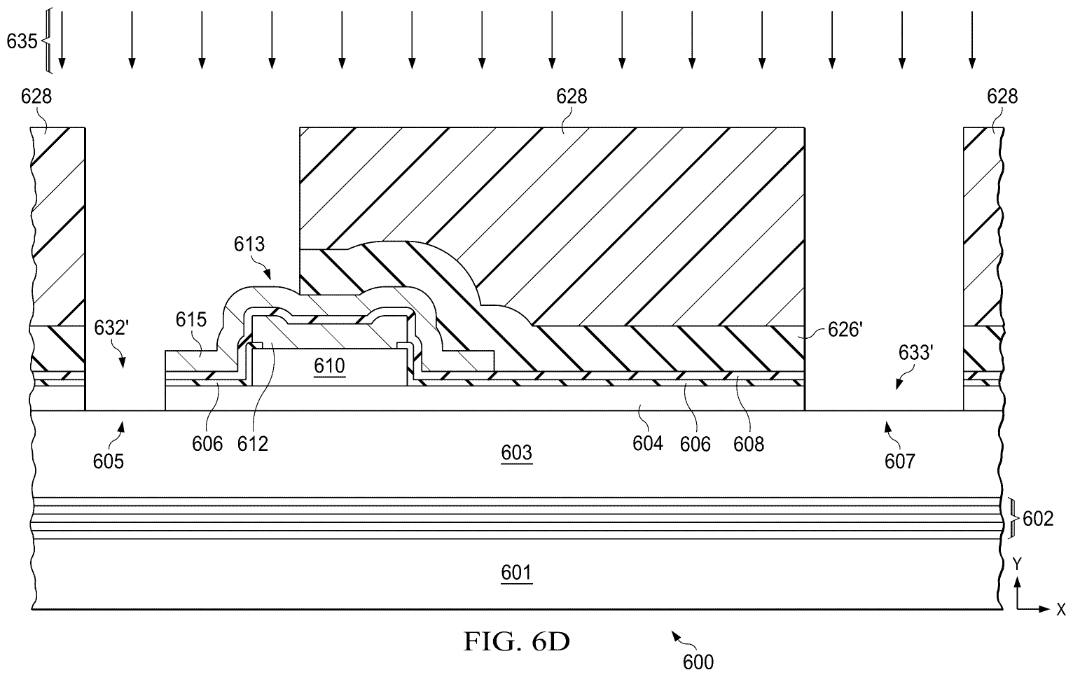

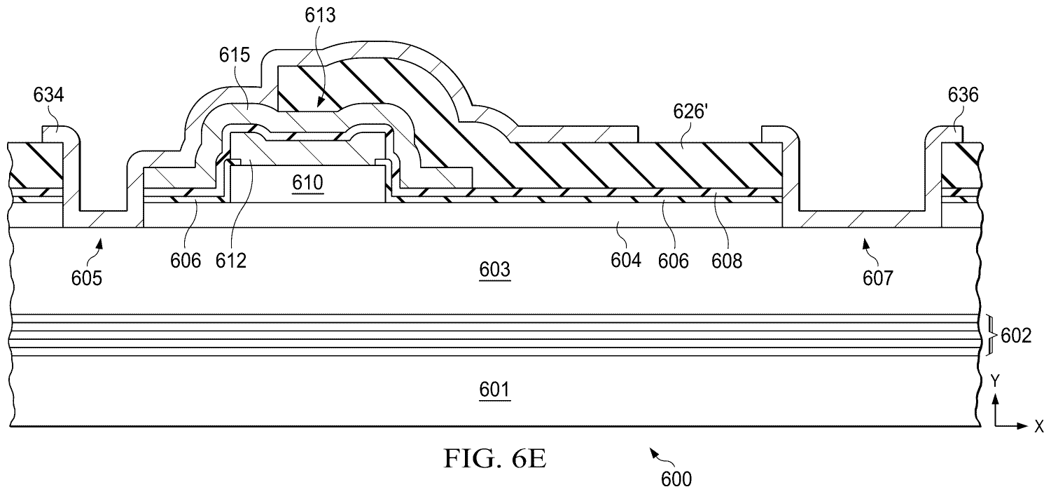

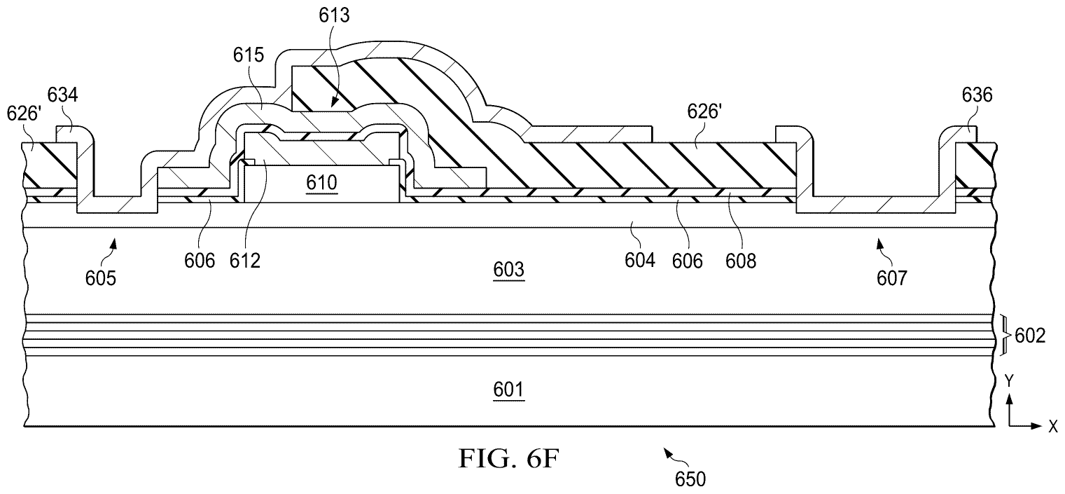

Referring now to FIG. 5, a flow diagram of a method 500 of forming a self-aligned contact using a field plate of a field effect transistor (FET) is illustrated, in accordance with various examples of the present disclosure. In various examples, method 500 may be used to form a field plate allowing for self-aligned contact openings in semiconductor devices, such as high electron mobility transistors (HEMTs). Additional processes can be provided before, during, and after method 500. As described below, method 500 is described with reference to FIGS. 6A-6F.

In that regard, FIGS. 6A-6F are diagrammatic cross-sectional views of a device 600 at various stages of fabrication (such as those associated with method 500 of FIG. 5) according to various aspects of the present disclosure. In various examples, device 600 may be an enhancement mode (E-mode) HEMT. Device 600 may be rated for a low voltage, a medium voltage, or a high voltage application as described above with respect to device 200. Additional features can be added to device 600, and some features described below can be replaced, modified, or eliminated in other examples of device 600. Device 600 (e.g., as depicted in FIG. 6F) includes similar components to device 200 described above in FIGS. 2A-2I, including a semiconductor substrate 601, transition layers 602, a channel layer 603, a barrier layer 604, a source region 605, a drain region 607, a first dielectric layer 606, a second dielectric layer 608, a gate layer 610, a gate electrode 612, a gate stack 613, a third dielectric layer 626′, a source contact 634, and a drain contact 636, descriptions of which may not be repeated below.

At steps 502, 504, 506, and 508 of FIG. 5, a III-N semiconductor layer is formed over a substrate, a gate structure is formed over the III-N semiconductor layer, a field plate is formed over the gate structure, and a dielectric layer is formed over the field plate such that the dielectric layer covers the field plate. As shown in FIG. 6A, device 600 is manufactured using processing steps similar to those described above with respect to FIGS. 2A-2F, descriptions of the processing steps will not be repeated. Barrier layer 604 is formed over semiconductor substrate 601. Gate layer 610 is formed over barrier layer 604 and first dielectric layer 606 is formed over barrier layer 604 and gate layer 610. Gate electrode 612 is formed over first dielectric layer 606 and gate layer 610. Second dielectric layer 608 is formed over first dielectric layer 606 and gate electrode 612. Field plate 615 is formed over second dielectric layer 608. Third dielectric layer 626 is formed over second dielectric layer 608 and field plate 615. A second photoresist layer 628 is formed over third dielectric layer 626 and openings 630 are formed therethrough. Each of these steps has been described previously.

In various examples, field plate 615 may be a conductive layer such as metal or metal alloy. In various examples, the metal and/or metal alloy may include titanium and/or tungsten. In some examples, field plate 615 may be a titanium-containing layer or a tungsten-containing layer. In some examples, field plate 615 may be one or more layers of titanium tungsten (TiW). In various examples, field plate 615 may be a single layer of metal or metal alloy layer. In various examples, field plate 615 may be a multilayered field plate formed of multiple layers have the same or similar compositions. In various examples, field plate 615 may be a multilayered field where each layer has a different material composition.

At step 510 of FIG. 5, a first etching process 627 is performed using a first etchant to remove a first portion of the dielectric layer. As shown in FIG. 6B, a first etching process is performed to remove a portion of third dielectric layer 626, forming an etched dielectric layer 626′ having a recess 631 therein. As described below, third dielectric layer 626 is etched so as to not expose field plate 615 because some etchants easily etch through the metals and/or metal alloys forming field plate 615. For example, in various examples, when field plate 615 includes titanium tungsten, sulfur hexafluoride (SF₆) and/or boron trichloride (BCl₃) etchants etch quickly through titanium tungsten which in turn degrades the structural and/or electrical integrity of field plate 615.

To address this issue, first etching process 627 may include, in various examples, one or more etching processes tuned to avoid exposing field plate 615. In various examples, the one or more etching processes may include a wet etching process, a dry etching process, or a combination thereof. The one or more processes may be tuned to remove portions of third dielectric layer 626. Different parameters of the first etching process may be tuned for the desired application, including an etchant type, an etchant flow rate, a chamber pressure, a top radio frequency (RF) power, a bottom RF power, and a process time. In various examples, the etchant may be sulfur hexafluoride (SF₆) and/or boron trichloride (BCl₃). A portion of third dielectric layer 626 is etched to not expose field plate 615 because the etchants SF₆ and BCl₃ easily etch some metals included in field plate 615. Accordingly, the first etching process may be used to remove most of third dielectric layer 626 while not etching field plate 615. In various examples, the flow rate of the SF₆ etchant may be about 40 sccm to about 70 sccm, and more specifically, about 50 sccm to about 60 sccm. In various examples the flow rate of the BCl₃ etchant may be about 10 sccm to about 40 sccm, and more specifically, about 20 sccm to about 30 sccm. In various examples, the chamber pressure may be about 5 mTorr to about 20 mTorr, and more specifically, about 8 mTorr to about 15 mTorr. In various examples, the top RF power may be about 150 W to about 350 W, and more specifically, about 225 W to about 275 W. In various examples, the bottom RF power may be about 50 W to about 150 W, and more specifically, about 75 W to about 115 W. In various examples, the process time may be about 35 seconds to about 65 seconds, and more specifically, about 45 seconds to about 55 seconds.

At step 512 of FIG. 5, a second etching process is performed using a second etchant to remove a second portion of the first dielectric layer and at least a portion of the III-N semiconductor layer to form a contact trench. As shown in FIG. 6C, a second etching process 629 removes a portion of etched dielectric layer 626′, second dielectric layer 608, first dielectric layer 606, and at least a portion of barrier layer 604 to form a source contact trench 632 and a drain contact trench 633. Moreover, as described below, second etching process 629 uses a different etchant and/or other process parameters than first etching process 627 to remove the exposed portions of etched dielectric layer 626′, second dielectric layer 608, first dielectric layer 606, and barrier layer 604 in order to avoid etching field plate 615. That is, as shown in FIG. 6C, second etching process 629 etches through these various layers to expose field plate 615 while performing little to no etching of field plate 615.

Second etching process 629 may include, in various examples, one or more etching processes. In various examples, the one or more etching processes may include a wet etching process, a dry etching process, or a combination thereof. The one or more processes may be tuned to remove portions of etched dielectric layer 626′, second dielectric layer 608, first dielectric layer 606, and barrier layer 604 while performing little to no etching of field plate 615. Different parameters of the second etching process 629 may be tuned for the desired application, including an etchant type, an etchant flow rate, a chamber pressure, a top RF power, a bottom RF power, and a process time. In various examples, the etchant may be trifluoromethane (CHF₃) in the presence of argon (Ar) gas. In various examples, the flow rate of the CHF₃ etchant may be about 5 sccm to about 25 sccm, and more specifically, about 10 sccm to about 20 sccm. In various examples, the flow rate of the Ar gas may be about 70 sccm to about 100 sccm, and more specifically, about 80 sccm to about 90 sccm. In various examples, the chamber pressure may be about 3 mTorr to about 15 mTorr, and more specifically, about 5 mTorr to about 10 mTorr. In various examples, the top RF power may be about 250 W to about 400 W, and more specifically, about 300 W to about 350 W. In various examples, the bottom RF power may be about 75 W to about 200 W, and more specifically, about 100 W to about 150 W. In various examples, the process time may be about 80 seconds to about 180 seconds, and more specifically, about 100 seconds to about 150 seconds.

Referring now to FIG. 6D, an optional third etching process 635 may be performed. Specifically, third etching process 635 may etch through the exposed portions of barrier layer 604 in source contact trench 632 and drain contact trench 633 to expose portions of channel layer 603 to form an extended source contact trench 632′ and an extended drain contact trench 633′, respectively. In various examples, source contact trench 632′ and drain contact trench 633′ may extend into channel layer 603. In various examples, the third etching process 635 may use boron trichloride (BCl₃) and/or chlorine (Cl₂) as the etchant. In various examples, the flow rate of the BCl₃ etchant may be about 5 sccm to about 35 sccm, and more specifically, about 15 sccm to about 25 sccm. In various examples the flow rate of the Cl₂ etchant may be about 60 sccm to about 100 sccm, and more specifically, about 75 sccm to about 85 sccm. In various examples, the chamber pressure may be about 3 mTorr to about 20 mTorr, and more specifically, about 5 mTorr to about 15 mTorr. In various examples, the top RF power may be about 150 W to about 350 W, and more specifically, about 225 W to about 275 W. In various examples, the bottom RF power may be about 20 W to about 50 W, and more specifically, about 30 W to about 40 W. In various examples, the process time may be about 5 seconds to about 25 seconds, and more specifically, about 8 seconds to about 15 seconds.

At step 514 of FIG. 5, a contact is formed in the contact trench. As shown in FIG. 6E, source contact 634 is formed in source contact trench 632′ and drain contact 636 is formed in drain contact trench 633′. The process of forming source contact 634 and drain contact 636 is similar to the process of forming source contact 234 and drain contact 236 described above in FIG. 2I.

Referring now to FIG. 6F, an alternative device 650 is shown. Alternative device 650 is similar to device 600 and may be manufactured using the processes described above for device 600. Alternative device 650 omits third etching process 635 described above in FIG. 6D that etches through barrier layer 604 and instead keeps a portion of barrier layer 604 disposed above channel layer 603 as shown in FIG. 6C. Source contact 634 and drain contact 636 are subsequently formed in source contact trench 632 and drain contact trench 633, respectively. As shown, source contact 634 and drain contact 636 extend into barrier layer 604 without extending to channel layer 603 of semiconductor substrate 601 because portions of barrier layer 604 remain disposed between channel layer 603 and source contact 634 and drain contact 636 as a result of third etching process 635 being omitted.

After the formation of source contact 634 and drain contact 636, additional processing steps may occur to devices 600 and 650. For example, an inter-layer dielectric layer (ILD) may be formed over etched third dielectric layer 626′, source contact 634 and drain contact 636. The ILD layer may be a single dielectric layer or may include multiple dielectric layers of a same dielectric material or different dielectric materials. In various examples, the ILD layer may include silicon nitride, a silicon oxide-based material (such as a phosphosilicate glass (PSG) or a tetraethyl orthosilicate (TEOS) oxide), polytetrafluoroethylene, or the like. Additionally, respective metal vias may be formed through the ILD layer to connect to source contact 634 and drain contact 636. The metal vias may each include (i) one or more metal-barrier and/or adhesion layers (e.g., titanium nitride (TiN), tantalum nitride (TaN), the like, or a combination thereof) conformally in a respective opening through the ILD layer and (ii) a fill metal (e.g., aluminum (Al), copper (Cu), tungsten (W), the like, or a combination thereof) over and/or on the metal-barrier and/or adhesion layer(s). Also, one or more metal lines may be formed over and on (and electrically connected to) the metal vias. The metal lines may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

Although devices 600 and 650 are described and shown as being E-mode HEMTs, the present disclosure is not limited to this implementation. For example, as described above, it is understood that the methods and structures disclosed herein are applicable to both E-mode HEMTs and D-mode HEMTs. That is, such self-aligned contacts can be connected to one or more field plates disposed over the gate stacks as described herein independent of the presence of gate layer 610 in the gate stack. Additionally, for example, one or more of the described self-aligned contacts can be formed as either a source contact and/or a drain contact of HEMTs (or other FETs, such as GaN FETs, silicon-based FETs, SiC-based FETs, or the like).

As described above, disclosed herein are methods of fabrication of semiconductor devices, such as HEMTs, utilizing a field plate for forming self-aligned contacts. Method 500 described above, provides a process for using a field plate (e.g. field plate 615) that includes titanium and/or tungsten (e.g. titanium tungsten (TiW)). Specifically, method 500 utilizes more than one etching process (e.g. first etching process 627, second etching process 629 and/or third etching process 635) to form contact trenches. That is, method 500 improves the fabrication of semiconductor devices by implementing multiple etching processes (e.g. first etching process 627, second etching process 629 and/or third etching process 635) that prevent and/or mitigate damage to field plate 615 that may otherwise occur during the formation of self-aligned contacts. As a result, method 500 allows for the use of multiple etchants through different etching steps that have a high etch selectivity towards the surrounding material layers (e.g. third dielectric layer 626, second dielectric layer 608, first dielectric layer 606 and/or barrier layer 604) during the formation of contact trenches without damaging the structural and/or electrical integrity of field plate 615. By minimizing etching of field plate 615 during fabrication, method 500 improves the function of field plate 615 as both a field plate and a contact etch stop during a self-aligned contact formation process.

Accordingly, the methods and devices disclosed herein provide an improved field plate for use in self-aligned contact formation. A device described herein, in various examples, has a field plate that includes aluminum (Al), cobalt (Co), silicon chromium (SiCr), and/or silicon carbide chromium (SiCCr). The use of these materials provides good etch selectivity between surrounding material layers and the field plate, reducing etching of the field plate during the formation of the contact trench. Another device described herein, in various examples, includes a field plate having two conductive layers including a titanium (Ti) layer and an aluminum (Al) layer. Another device described herein, in various examples, has three conductive layers, including a titanium (Ti) layer, an aluminum (Al) layer, and a titanium tungsten (TiW) layer. These multilayered field plates described herein reduce film peeling during subsequent steps with no negative impact to the function as a field plate or an etch stop. Also described are methods for forming, including etching, the field plates having different conductive layers. The methods and devices disclosed herein allow for the manufacture of semiconductor devices, such as HEMTs, having self-aligned contact structures and with little to no peeling of aluminum layers of the field plate used therein. Additionally, described are methods that improve the fabrication of semiconductor devices, such as HEMTs, by implementing multiple etching processes that prevent and/or mitigate damage to field plates that may otherwise occur during the formation of self-aligned contacts.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A semiconductor device comprising:
a III-N semiconductor layer disposed over a substrate;
a gate structure disposed over the III-N semiconductor layer;
a field plate disposed over the gate structure, the field plate including:
a first conductive layer disposed over the gate structure;
a second conductive layer disposed over the first conductive layer, the second conductive layer having a different material composition than the first conductive layer; and
a third conductive layer disposed over the second conductive layer, the third conductive layer having a different material composition than the first and second conductive layers; and
a contact coupled to the field plate and to the III-N semiconductor layer.

2. The semiconductor device of claim 1, wherein the substrate includes a source region, and
wherein the contact extends to the source region.

3. The semiconductor device of claim 1, wherein the first conductive layer includes a first metal material,
wherein the second conductive layer includes a second metal material that has a different material composition than the first metal material; and
wherein the third conductive layer includes a third metal material that has a different material composition than either of the first and second metal materials.

4. The semiconductor device of claim 1, wherein the first conductive layer includes titanium,
wherein the second conductive layer includes aluminum; and
wherein the third conductive layer includes tungsten.

5. The semiconductor device of claim 1, wherein the first conductive layer includes titanium,
wherein the second conductive layer includes one of cobalt, silicon chromium, or silicon carbon chromium, and
wherein the third conductive layer includes tungsten.

6. The semiconductor device of claim 1, wherein the III-N semiconductor layer includes an aluminum gallium nitride (AlGaN) material, and
wherein the gate structure includes a doped gallium-nitride (GaN) layer and a metal layer disposed over the doped GaN layer.

7. The semiconductor device of claim 1, wherein the second conductive layer of the field plate is thicker than either of the first conductive layer and the third conductive layer of the field plate.

8. A method comprising:
forming a III-N semiconductor layer over a substrate;
forming a gate structure over the III-N semiconductor layer;
forming a first conductive layer over the gate structure;
forming a second conductive layer over the first conductive layer, the second conductive layer having a different material composition than the first conductive layer;
patterning the second conductive layer, wherein the patterning of the second conductive layer forms a protective layer on a sidewall of the patterned second conductive layer;
patterning the first conductive layer while using the protective layer and the patterned second conductive layer as a mask;
forming a first dielectric layer over the patterned first and second conductive layers;
forming a contact opening through the first dielectric layer to at least the III-N semiconductor layer, wherein the patterned first and second conductive layers are exposed in the contact opening; and
forming a contact in the contact opening.

9. The method of claim 8, wherein the second conductive layer includes aluminum and the first conductive layer includes titanium, and
wherein the patterning of the second conductive layer includes performing a first etching process using a first etchant at a first bias power, and
wherein the patterning of the first conductive layer includes performing a second etching process using the first etchant at a second bias power, the second bias power being different than the first bias power.

10. The method of claim 9, wherein the forming the second conductive layer further comprises:
performing an aluminum deposition process at a temperature of less than 100° C. and in the absence of an argon gas.

11. The method of claim 9, wherein the first etchant includes boron trichloride (BCl₃) and chlorine (Cl₂).

12. The method of claim 8, further comprising:
forming a third conductive layer over the second conductive layer, the third conductive layer having a different material composition than either of the first and second conductive layers; and
patterning the third conductive layer prior to patterning the second conductive layer, and
wherein the patterning of the second conductive layer includes using the patterned third conductive layer as a mask.

13. The method of claim 12, wherein the forming of the contact in the contact opening includes forming the contact directly connected to the patterned first, second, and third conductive layers.

14. The method of claim 13, wherein the III-N semiconductor layer includes an aluminum gallium nitride (AlGaN) material,
wherein the gate structure includes a doped gallium-nitride (GaN) layer and a conductive layer disposed over the doped GaN layer,
wherein the third conductive layer includes tungsten,
wherein the second conductive layer includes aluminum, and
wherein the first conductive layer includes titanium.

15. The method of claim 14, wherein the patterning of the third conductive layer includes using a first etchant, the first etchant including sulfur hexafluoride (SF₆), and
wherein the patterning of the first conductive layer or the second conductive layer includes using a second etchant, the second etchant including boron trichloride (BCl₃) and chlorine (Cl₂).

16. The method of claim 8, further comprising:
removing the protective layer from the sidewall of the patterned second conductive layer after the patterning of the first conductive layer.

17. The method of claim 8, further comprising:
performing an annealing process, after forming the second conductive layer, at a temperature of about 550° C. to about 800° C.

18. A method comprising:
forming a III-N semiconductor layer over a substrate;
forming a gate structure over the III-N semiconductor layer;
forming a field plate over the gate structure;
forming a first dielectric layer over the field plate such that the first dielectric layer covers the field plate;
performing a first etching process using a first etchant to remove a first portion of the first dielectric layer, wherein a second portion of the first dielectric layer still covers the field plate after the performing of the first etching process;
performing a second etching process using a second etchant to remove the second portion of the first dielectric layer and at least a portion of the III-N semiconductor layer to form a contact opening, the second etchant being different than the first etchant; and
forming a contact in the contact opening.

19. The method of claim 18, further comprising:
performing a third etching process using a third etchant to remove a portion of the III-N semiconductor layer through the contact opening prior to forming the contact in the contact opening, the third etchant being different than either of the first and second etchants.

20. The method of claim 19, wherein the first etchant includes sulfur hexafluoride (SF₆),
wherein the second etchant includes trifluoromethane (CHF₃), and
wherein the third etchant includes chlorine (Cl₂).

21. The method of claim 18, further comprising:
forming a second dielectric layer over the gate structure and the III-N semiconductor layer prior to forming the field plate over the gate structure, and
wherein performing the second etching process using the second etchant to remove the second portion of the first dielectric layer and at least the portion of the III-N semiconductor layer to form the contact opening further includes removing a portion of the second dielectric layer disposed on the III-N semiconductor layer.

22. The method of claim 18, wherein the field plate includes titanium tungsten (TiW).
